(19) United States
(12) Patent Application Publication
(10) Pub. No.: US 2024/0224787 A1
(43) Pub. Date: Jul. 4, 2024

(54) ORGANIC ELECTRO LUMINESCENCE DEVICE

(71) Applicant: Korea University Research and Business Foundation, Sejong Campus, Sejong (KR)

(72) Inventors: Sangook Kang, Sejong (KR); Hojin Son, Sejong (KR)

(21) Appl. No.: 18/549,747

(22) PCT Filed: Mar. 8, 2022
(86) PCT No.: PCT/KR2022/003301

§ 371 Date: Feb. 21, 2024

(30) Foreign Application Priority Data
Mar. 8, 2021 (KR) 10-2021-0030320
Mar. 8, 2022 (KR) 10-2022-0029088

(51) Int. Cl. H10K 85/30; C09K 11/06; H10K 50/12; H10K 85/60

(52) U.S. Cl. CPC H10K 85/342; C09K 11/06; H10K 85/615; H10K 85/6572; C09K 2211/1044; C09K 2211/185; H10K 50/12

(57) ABSTRACT

The present invention relates to an organic electro luminescence device. The organic electro luminescence device comprises a light-emitting layer including an iridium complex of a specific structure and a host, thereby having a low driving voltage, high luminous efficiency, and a long lifespan, as well as emitting excellent blue phosphorescence.

### TECHNICAL FIELD

The present disclosure relates to an organic electroluminescent device, and more specifically to an organic electroluminescent device with low driving voltage, high luminous efficiency, and long lifespan characteristics as well as excellent blue phosphorescent emission.

### BACKGROUND ART

In the structure of an organic electroluminescent device (hereinafter referred to as “organic EL device”), application of a voltage between two electrodes injects holes from the anode and electrons from the cathode into the organic layer. When the injected holes and electrons are combined with each other, excitons are generated and then return to a ground state, emitting light.

Electron spin types of the formed excitons classify organic EL devices into fluorescent EL devices in which singlet excitons contribute to light emission and phosphorescent EL devices in which triplet excitons are responsible for light emission.

Theoretically, depending on the generation ratio, the internal quantum efficiency amounts to at the most 25% for fluorescent EL devices and to up to 100% for phosphorescent EL devices. For phosphorescence, high internal quantum efficiency may be obtained because triplets and singlets are involved in internal quantum efficiency, but in the case of fluorescence, only singlet transition occurs, so the maximum internal quantum efficiency is about a quarter of that of phosphorescence. As such, the phosphorescent EL devices have theoretically higher luminous efficiency than the fluorescence.

For phosphorescent EL devices, the light-emitting layer includes a host material and a dopant material that produces emission through energy transfer from the host material. Among the dopant materials are Ir compounds based on the (4, 6-F₂ppy) ₂Irpic or fluorinated ppy ligand structures that have been developed for blue light emission, and CBP materials are widely used as host materials. However, CBP materials provides insufficient energy transfer to blue-emitting dopants, suffering from the disadvantages of low blue-emission efficiency and short lifetime for the devices.

### DISCLOSURE OF INVENTION

### Technical Problem

The present disclosure aims to an organic EL device that not only exhibits low driving voltage, high luminous efficiency, and long lifespan characteristics, but also enables blue phosphorescent emission.

### Solution to Problem

In accordance with an aspect thereof, the present disclosure provides an organic EL device including: an anode: a cathode; and at least one organic layer disposed between the anode and the cathode and including a light-emitting layer, wherein the light-emitting layer includes an iridium complex represented by the following Chemical Formula 1 and a compound represented by the following Chemical Formula 2:

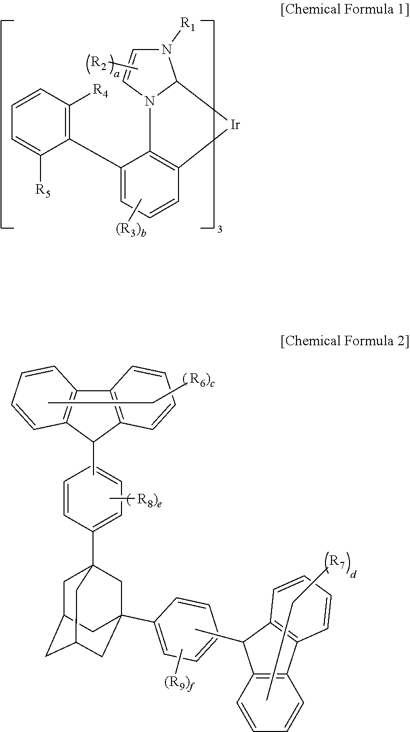

(wherein,
R₁ is an alkyl of C₁-C₂₀,
a is an integer of 0 to 2,
b is an integer of 0 to 3,
R₂ and R₃ are same or different and are each independently selected from the group consisting of a hydrogen atom, a deuterium atom, a halogen, a cyano, an alkyl of C₁-C₂₀, an alkenyl of C₂-C₄₀, an alkynyl of C₂-C₂₀, a cycloalkyl of C₃-C₂₀, a heterocycloalkyl of 3 to 20 nuclear atoms, an aryl of C₆-C₂₀, a heteroaryl of 5 to 20 nuclear atoms, an alkyloxy of C₁-C₂₀, and an aryloxy of C₆-C₂₀,
R₄ and R₅ are same or different and are each independently a hydrogen atom or an alkyl of C₁-C₂₀,
with at least one thereof being an alkyl of C₁-C₂₀,
c and d are each an integer of 0 to 8,
e and f are each an integer of 0 to 4, and
R₆ to R₉ are same or different and are each independently selected from the group consisting of a hydrogen atom, a deuterium atom, a halogen, a cyano, an alkyl of C₁-C₂₀, an alkenyl of C₂-C₄₀, an alkynyl of C₂-C₂₀, a cycloalkyl of C₃-C₂₀, a heterocycloalkyl of 3 to 20 nuclear atoms, an aryl of C₆-C₂₀, a heteroaryl of 5 to 20 nuclear atoms, an alkyloxy of C₁-C₂₀, and an aryloxy of C₆-C₂₀).

### Advantageous Effects of Invention

Equipped with a light-emitting layer including specific structures of iridium complexes and hosts, the organic EL device of the present disclosure exhibits low driving voltage, high luminous efficiency, and long lifespan characteristics as well as enabling excellent blue phosphorescent emission.

Furthermore, application of the organic EL device of the present disclosure allows for the provision of display panels with enhanced performance and lifespan.

### BRIEF DESCRIPTION OF DRAWINGS

FIG. 1 is a cross-sectional view showing the structure of an organic EL device according to an embodiment of the present disclosure.

FIG. 2 shows models of molecules for structures of fac-Ir(C\hat{ }C^{Ph})₃ of Comparative Synthesis Example 2 and fac-Ir(C\hat{ }C^{diMePh})₃ Of Synthesis Example 2.

FIG. 3 shows steady-state absorption spectra of Ir complexes synthesized in Synthesis Examples 1-2 and Comparative Synthesis Examples 1-3.

FIG. 4 shows steady-state emissive spectra of Ir complexes synthesized in Synthesis Examples 1-2 and Comparative Synthesis Examples 1-3.

FIG. 5 shows diagrams of parameters that affect energy gap (E₀) and relative nuclear displacement of the Ir complexes synthesized in Synthesis Examples 1-2 and Comparative Synthesis Example 2.

FIG. 6 is a graph showing parameters that affect energy gap (E₀) and relative nuclear displacement of the Ir complexes synthesized in Synthesis Examples 1-2 and Comparative Synthesis Example 2.

FIG. 7 shows cyclic voltammogram (CV) of Ir complexes synthesized in Synthesis Examples 1-2 and Comparative Synthesis Examples 1-3.

FIG. 8 is a diagram showing molecular orbital distributions and energy levels of Ir complexes synthesized in Synthesis Examples 1-2 and Comparative Synthesis Examples 1-3, as analyzed by DFT calculations.

FIG. 9 is a diagram showing optimized triplet excited state structures and energy levels (HSOMOS, LSOMOs, and ³MC state) of the Ir complexes synthesized in Synthesis Examples 1-2 and Comparative Synthesis Examples 1-3.

FIG. 10 is an energy diagram of Ir complexes synthesized in Synthesis Examples 1-2 and Comparative Synthesis Examples 1-3.

FIG. 11 shows models of molecule for optimized excited-state structures of the meridional Ir complexes synthesized in Synthesis Examples 1-2 and Comparative Synthesis Examples 1-3, as analyzed by DFT calculation.

FIG. 12 is a diagram showing the structures of the devices fabricated in Example 1 and Comparative Example 1, together with the energy levels of the individual materials used in the devices.

FIG. 13 shows plots illustrating performances of the devices fabricated in Example 1 and Comparative Example 1 in terms of J-V-L characteristic (a), current efficiency-current density (b), voltage efficiency (c), and external quantum efficiency (EQE) (d).

FIG. 14 shows electroluminescence spectra of OLEDs of Example 1 and Comparative Example 1.

FIG. 15 is a plot showing photophysical properties of host materials used in Example 2 and Comparative Example 2.

FIG. 16 is time-luminescence intensity plots of sample 1 and control sample 1.

### DESCRIPTION OF REFERENCE NUMERALS

100: anode,
200: cathode,
300: organic layer,
310: hole transport region,
311: hole injection layer,
312: hole transport layer,
320: light-emitting layer,
330: electron transport region,
331: electron transport layer,
332: electron injection layer

### BEST MODE FOR CARRYING OUT THE INVENTION

Advantages and features of the present disclosure and methods of accomplishing the same may be understood more readily by reference to the following detailed description of preferred embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the disclosure to those skilled in the art, and the present disclosure will only be defined by the appended claims. In some embodiments, process steps, device structures, and techniques well known in the art have not been described in detail in order to avoid obscuring the interpretation of the present disclosure. Like reference numerals will be used throughout to designate the same or like elements.

Otherwise defined, all terms used in the specification (including technical and scientific terms) may be used with meanings commonly understood by a person having ordinary knowledge in the art. Further, unless explicitly defined to the contrary, the terms defined in a generally-used dictionary are not ideally or excessively interpreted.

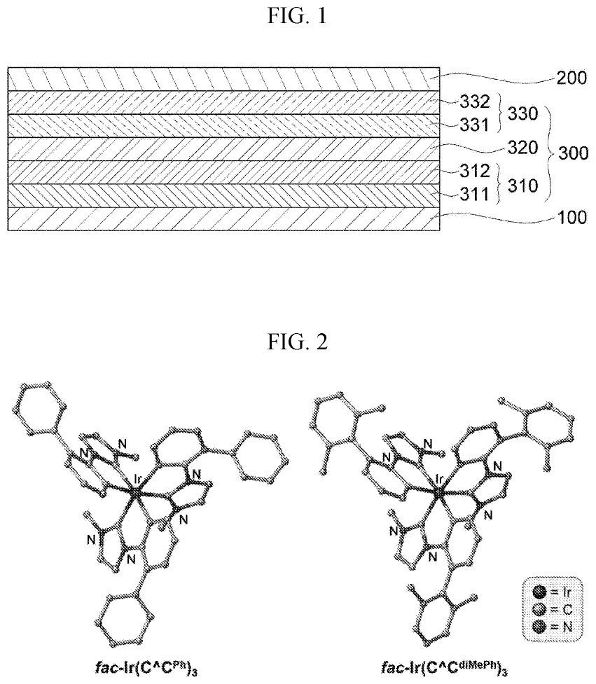

FIG. 1 is a schematic cross-sectional view of an organic EL device according to an embodiment. The organic EL device includes an anode (100), at least one organic layer (300), and a cathode (200) sequentially deposited on a substrate (not shown), wherein the organic layer includes a hole transport region (310), a light-emitting layer (320), and an electron transport region (330) and the light-emitting layer (320) contains an iridium complex represented by Chemical Formula 1 and a compound represented by Chemical Formula 2. Optionally, the organic EL device may further include a capping layer (not shown) disposed on the second electrode (200). With such a structure, the organic EL device of the present disclosure can exhibit excellent blue phosphorescent emission as well as possessing low driving voltage, high luminous efficiency, and long lifespan characteristics.

Below, each component of the organic EL device according to the present disclosure will be elucidated.

### (1) Anode

The organic EL device of the present disclosure includes the anode (100). The anode (100) may be disposed on a substrate and electrically connected to a driving thin film transistor to receive a driving current from the driving thin film transistor. Since the anode (100) includes or is formed of a material having a relatively high work function, it injects holes into an adjacent one of the organic layers, that is, the hole transport region (310) (e.g., a hole injection layer (311)).

So long as it is typically known in the art, any material may be used for the anode with no particular limitations imparted thereto. Examples thereof include metals, such as vanadium, chromium, copper, zinc, and gold; alloys thereof; metal oxides such as zinc oxide, indium oxide, indium tin oxide (ITO), and indium zinc oxide (IZO); combinations of metals and oxides such as ZnO:Al and SnO₂:Sb; conductive polymers such as polythiophene, poly(3-methylthiophene), poly[3,4-(ethylene-1,2-dioxy)thiophene] (PEDT), polypyrrole, and polyaniline; carbon black, but are not limited thereto.

Any method that is known in the art may be employed for preparing the anode, with no limitations thereto. For example, the anode may be formed by coating the anode material on a substrate through a known thin film forming method such as a sputtering method, an ion plating method, a vacuum deposition method, or a spin coating method.

The substrate may be a plate-shaped member for supporting the organic EL device, and include, for example, a silicon wafer, quartz, a glass plate, a metal plate, a plastic film, and a sheet, but with no limitations thereto.

### (2) Cathode

In the organic EL device of the present disclosure, the cathode (200) is disposed opposing the anode, and specifically, disposed on the electron transport region (330). Since the cathode (200) includes a material having a relatively low work function, it may inject electrons into an adjacent organic layer, that is, the electron transport region (330) (e.g., an electron injection layer (332)).

So long as it is typically known in the art, any cathode material may be used without particular limitations. Examples of the cathode material include metals, such as magnesium, calcium, sodium, potassium, titanium, indium, yttrium, lithium, gadolinium, aluminum, silver (Ag), tin, and lead; alloys thereof; and a multi-layer structure material such as LiF/Al or LiO₂/Al, but are not limited thereto.

No particular limitations are imparted to methods for preparing a cathode, and like the anode, the cathode may be prepared through a conventional method known in the art. By way of example, the cathode may be formed by coating the cathode material on at least one organic layer (300), specifically on the electron transport region, for example, the electron injection layer (332), through the above-described thin film forming method.

### (3) Organic Layer

In the organic EL device of the present disclosure, at least one organic layer (300) is disposed between the anode (100) and the cathode (200) and includes a hole transport region (310), a light-emitting layer (320), and an electron transport region (330).

According to an embodiment, as shown in FIG. 1, the at least one organic layer (300) may include a hole injection layer (311), a hole transport layer (312), a light-emitting layer (320), an electron transport layer (331), and an electron injection layer (332) that are sequentially disposed on the anode (100).

Hereinafter, each organic layer will be described.

### 1) Hole Transport Region

In the organic EL device (100) of the present disclosure, the hole transport region (310) is a portion of the organic layer (300) disposed on the anode (100), and serves to allow holes injected from the anode (100) to migrate into another adjacent one of the organic layers, specifically to the light-emitting layer (320).

The hole transport region (310) may include at least one selected from the group consisting of a hole injection layer (311) and a transport layer (312).

In an embodiment, as shown in FIG. 1, the hole transport region (310) may include a hole injection layer (311) and a hole transport layer (312) that are sequentially stacked on the anode (100).

A material forming the hole injection layer (311) and the hole transport layer (312) in the present disclosure is not particularly limited as long as it has a low hole injection barrier and a high hole mobility, and any material for typically used the hole injection/transport layer in the art may be employed without limitation. In this regard, respective materials accounting for the hole injection layer (311) and the hole transport layer (312) may be same or different from each other.

Specifically, the hole injection layer (311) may include a hole injection material known in the art. Non-limiting examples of the hole injection material may phthalocyanine such include compounds as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-tris(3-methylphenylphenylamino) triphenylamine), TDATA (4,4′4″-Tris(N,N-diphenylamino)triphenylamine), 2TNATA (4,4′,4″-tris{N,-(2-naphthyl)-N-phenylamino}-triphenylamine), PEDOT/PSS (Poly(3,4-ethylenedioxythiophene)/Poly(4-styrenesulfonate)), PANI/DBSA (Polyaniline/Dodecylbenzenesulfonic acid), PANI/CSA (Polyaniline/Camphor sulfonic acid), PANI/PSS ((Polyaniline)/Poly(4-styrenesulfonate)), and the like, which may be used solely or in combination of two or more thereof.

The hole transport layer (312) includes a hole transport material known in the art. Non-limiting examples of the hole transport material may include carbazole-based derivatives such as N-phenylcarbazole and polyvinylcarbazole; fluorene-based derivatives; amine-based derivatives; triphenylamine-based derivatives such as TPD (N,N′-bis(3-methylphenyl)-N,N′-diphenyl-[1,1-biphenyl]-4,4′-diamine) and TCTA (4,4′,4″-tris(N-carbazolyl)triphenylamine); NPB (N,N′-di(1-naphthyl)-N,N′-diphenylbenzidine), TAPC (4,4′-cyclohexylidene bis[N,N-bis(4-methylphenyl)benzenamine]), and the like, which may be used solely or in combination of two or more thereof.

The hole transport region (310) may be formed through a conventional method known in the art. For example, a vacuum deposition method, a spin coating method, a casting method, a Langmuir-Blodgett (LB) method, an inkjet printing method, a laser printing method, a laser induced thermal imaging (LITI) method, and the like may be available, but with no limitations thereto.

### 2) Light-Emitting Layer

In the organic EL device of the present disclosure, the light-emitting layer (320) is a portion of the organic layer (300) disposed between the anode (100) and the cathode (200), and specifically disposed on the hole transport region 320. Specifically, the light-emitting layer (320) may be disposed on the hole transport layer (312) (see FIG. 1). The light-emitting layer (320) is a layer in which holes and electrons injected from the anode and the cathode, respectively, are combined to form excitons, and the color of light emitted by the organic EL device may vary depending on the material forming the light-emitting layer (320).

The light-emitting layer according to the present disclosure includes an iridium complex represented by Chemical Formula 1 and a compound represented by Chemical Formula 2. Thus, the organic EL device of the present disclosure not only possesses characteristics of low driving voltage, high efficiency, and long lifespan, but it can also exhibit excellent blue light emission characteristics. According to an embodiment, the organic EL device of the present disclosure can produce blue light emission with CIE coordinates where the x-value is 0.15-0.25 and the y-value is 0.08-0.20.

The iridium complex represented by Chemical Formula 1 is used as a dopant, specifically as a blue phosphorescent dopant.

In the iridium complex represented by Chemical Formula 1, R₁ may be an alkyl of C₁-C₂₀ and specifically an alkyl of C₁-C₁₀. According to an embodiment, R₁ may be selected from the group consisting of methyl, ethyl, n-propyl, iso-propyl, n-butyl, iso-butyl or sec-butyl, and tert-butyl.

In Chemical Formula 1 that accounts for the iridium complex, a is an integer of 0 to 2 and specifically 0 or 1. The case where a is 0 indicates that any of the hydrogens is not substituted by the substituent R₂. When a is 1 or 2, the hydrogen (s) is (are) substituted by the substituent R₂. Given, the multiple R₂'s may be same or different and are each independently selected from the group consisting of a deuterium atom, a halogen, a cyano, an alkyl of C₁-C₂₀, an alkenyl of C₂-C₄₀, an alkynyl of C₂-C₂₀, a cycloalkyl of C₃-C₂₀, a heterocycloalkyl of 3 to 20 nuclear atoms, an aryl of C₆-C₂₀, a heteroaryl of 5 to 20 nuclear atoms, an alkyloxy of C₁-C₂₀, and an aryloxy of C₆-C₂₀, and specifically from the group consisting of a deuterium atom, a halogen, a cyano, an alkyl of C₁-C₂₀, an aryl of C₆-C₂₀, and a heteroaryl of 5 to 20 nuclear atoms.

In Chemical Formula 1 accounting for the iridium complex, b is an integer of 0 to 3 and specifically 0 or 1. The case where b is 0 mean that none of the hydrogens are substituted by the substituent R₃. When b is an integer of 1 to 3, the hydrogen (s) is (are) substituted by the substituent R₃. Given, the multiple R₃'s may be same or different and are each independently selected from the group consisting of a deuterium hydrogen, a halogen, a cyano, an alkyl of C₁-C₂₀, an alkenyl of C₂-C₄₀, an alkynyl of C₂-C₂₀, a cycloalkyl of C₃-C₂₀, a heterocycloalkyl of 3 to 20 nuclear atoms, an aryl of C₆-C₂₀, a heteroaryl of 5 to 20 nuclear atoms, an alkyloxy of C₁-C₂₀, and an aryloxy of C₆-C₂₀ and specifically from the group consisting of a deuterium atom, a halogen, a cyano, an alkyl of C₁-C₂₀, an aryl of C₆-C₂₀, and a heteroaryl of 5 to 20 nuclear atoms.

In Chemical Formula 1 accounting for the iridium complex, R₄ and R₅ may be same or different and are each independently a hydrogen atom or an alkyl of C₁-C₂₀ and specifically an alkyl of C₁-C₁₀. However, at least one of R₄ and R₅ may be an alkyl of C₁-C₂₀ and specifically an alkyl of C₁-C₁₀. Examples of the alkyl include, but are not limited to, ethyl, n-propyl, iso-propyl, n-butyl, iso-butyl, and sec-butyl, tert-butyl.

The iridium complex represented by Chemical Formula 1 may be an iridium complex represented by the following Chemical Formula 1a, but is not limited thereto.

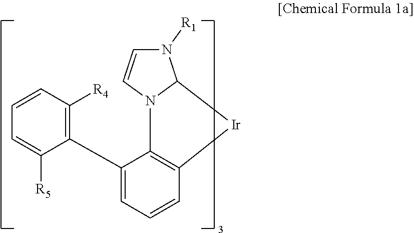

wherein,
R₁, R₄, and R₅ are as defined in Chemical Formula 1.

In the iridium complex represented by Chemical Formula 1, the

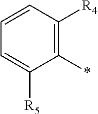

moiety is bonded to the benzene ring of the parent ligand

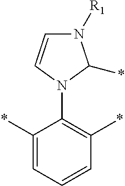

moiety at an angle of 0 to 90° with regard to the plane of the parent ligand moiety. According to an embodiment, the

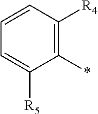

moiety is orthogonal to the plane of the

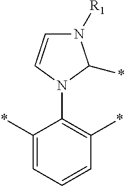

moiety and is bonded to the benzene ring. With such a structure, the iridium complex of Chemical Formula 1 increases in the energy of the ligand skeleton, which is the luminescent source. In addition, the addition of a radial structure centered on the iridium metal can achieve deep blue luminescence and enhance the lifespan of the device. Furthermore, the iridium complex of Chemical Formula 1 can achieve deep blue luminescence even in low-temperature or solid-state luminescence.

The iridium complex represented by Chemical Formula 1 may be an iridium complex represented by the following Chemical Formula 1b or 1c, but with no limitations thereto.

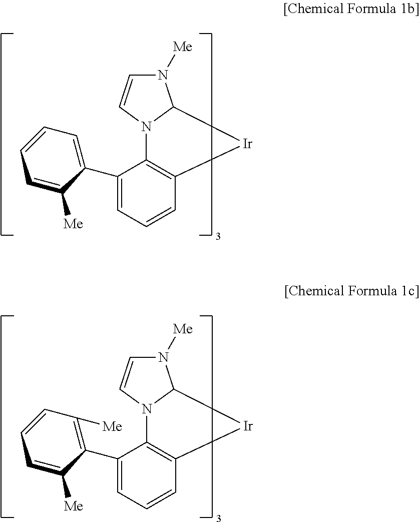

wherein, Me stands for methyl.

In the light-emitting layer, the compound represented by Chemical Formula 2 is used as a host and specifically as a blue phosphorescent host and is responsible, together with the iridium complex of Chemical Formula 1, for deep-blue phosphorescent emission.

In the compound represented by Chemical Formula 2, c and d are each an integer of 0 to 8 and specifically 0 or 1, and e and f are each an integer of 0 to 4 and specifically 0 or 1. The case where c, d, e, and f are each 0 means that any of the hydrogens is not substituted by the substituent (R₆, R₇, R₈, and R₉). When c and d are each an integer of 1 to 8 and e and f are each an integer of 1 to 3, any of the hydrogens is substituted by the substituents (R₆, R₇, R₈, R₉). In this regard, the multiple R₆'s, the multiple R₇'s, the multiple R₈'s, and the multiple R₉'s may be same or different and are each selected from the group consisting of a deuterium atom, a halogen, a cyano, an alkyl of C₁-C₂₀, an alkenyl of C₂-C₄₀, an alkynyl of C₂-C₂₀, a cycloalkyl of C₃-C₂₀, a heterocycloalkyl of 3 to 20 nuclear atoms, an aryl of C₆-C₂₀, a heteroaryl of 5 to 20 nuclear atoms, an alkyloxy of C₁-C₂₀, and an aryloxy of C₆-C₂₀ and specifically from the group consisting of a deuterium atom, a halogen, a cyano, an alkyl of C₁-C₂₀, an aryl of C₆-C₂₀, and a heteroaryl of 5 to 20 nuclear atoms.

The compound represent by Chemical Formula 2 may be a compound represented by the following Chemical Formula 2a, but with no limitations thereto.

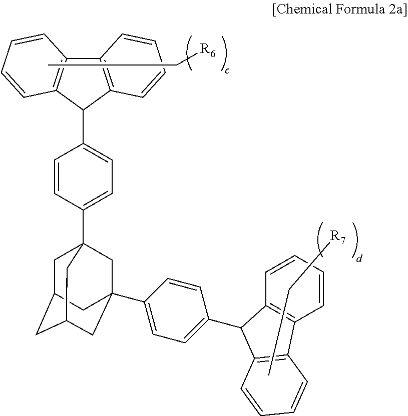

wherein, c, d, R₆, and R₇ are each defined as in Chemical Formula 2.

The iridium complex represented by Chemical Formula 1 and the compound represented by Chemical Formula 2 may be used (mixed) at a weight ratio of 1:99-30:70.

The light-emitting layer (320) may be a single layer or a multilayer structure composed of two or more layers. In this regard, when the light-emitting layer (320) includes a plurality of layers, the organic EL device may emit light of various colors. Specifically, the present disclosure may provide an organic EL device in which a plurality of light-emitting layers including heterogeneous materials are arranged in series to express a mixed color. In addition, when employed, a plurality of light-emitting layers requires an increased driving voltage in the device, but makes the current value constant in the organic EL device, thus enabling the provision of an organic EL device with improved luminous efficiency by the number of light-emitting layers.

The light-emitting layer (320) may be constructed through a conventional method known in the art. For example, a vacuum deposition method, a spin coating method, a casting method, a Langmuir-Blodgett (LB) method, an inkjet printing method, a laser printing method, a laser induced thermal imaging (LITI) method, and the like are available, but with no limitations thereto. In an embodiment, the light-emitting layer may be formed by co-depositing the iridium complex of chemical formula 1 and the compound (host) of chemical formula 2.

### 3) Electron Transport Region

In the organic EL device according to the present disclosure, the electron transport region (330) is an organic layer disposed on the light-emitting layer (320), functioning to move electrons injected from the cathode (200) to the light-emitting layer (320).

The electron transport region (330) may include at least one selected from the group consisting of the electron transport layer (331) and the electron injection layer (332).

In an embodiment, as shown in FIG. 1, the electron transport region (330) may include an electron transport layer (331) and an electron injection layer (332) which are sequentially disposed on a light-emitting layer (320).

In the electron transport region (330) according to the present disclosure, any electron transport material that facilitates electron injection and has high electron mobility may be used for the electron transport layer (331) without limitations. Non-limiting examples of the electron transport material include oxazole-based compounds, isoxazole-based compounds, triazole-based compounds, isothiazole-based compounds, oxadiazole-based compounds, thiadiazole-based compounds, perylene-based compounds, aluminum complexes [e.g., Alq₃ (tris(8-quinolinolato)-aluminum), BAlq, SAlq, Alph₃, Almq₃], and gallium complexes (e.g., Gaq′2OPiv, Gaq′2OAc, 2(Gaq′2)), which may be used solely or in combination thereof.

In addition, any electron injection material that facilitates electron injection and has high electron mobility may be used for the electron injection layer (332) without limitations. Non-limiting examples of the electron injection material may include LiF, Li₂O, Bao, NaCl, and CsF; lanthanide metals such as Yb; a metal halide such as RbCl or RbI, and the like, which may be used solely or in combination thereof.

The electron transport region (330) according to the present disclosure, specifically, the electron transport layer (331) and/or the electron injection layer (332) may be co-deposited with an n-type dopant to facilitate injection of electrons from the cathode. In this regard, any alkali metal complex compound known in the art may be used as the n-type dopant, without limitations, and examples thereof include alkali metals, alkaline earth metals, and rare earth metals.

The electron transport region (330) may be formed through a conventional method known in the art. For example, a vacuum deposition method, a spin coating method, a casting method, a Langmuir-Blodgett (LB) method, an inkjet printing method, a laser printing method, and a laser induced thermal imaging (LITI) method are available, but with no limitations thereto.

### 4) Light-Emitting Auxiliary Layer

The organic EL device 100 of the present disclosure may further include a light-emitting auxiliary layer, although not shown, disposed between the hole transport region (310) and the light-emitting layer (320).

The light-emitting auxiliary layer serves to control a thickness of the organic layer 300, while transporting holes from the hole transport region (310) to the light-emitting layer (320) or blocking the migration of electrons and/or excitons. In particular, the light-emitting auxiliary layer has a high LUMO value to prevent electrons from migrating to the hole transport layer (312) and has a high triplet energy to prevent excitons of the light-emitting layer (320) from being diffused to the hole transport layer (312).

The light-emitting auxiliary layer may include a hole transport material and may include or be formed of a material the same as a material of the hole transport region. In addition, the light-emitting auxiliary layers of the red, green, and blue organic EL devices may include or be formed of the same material.

No particular limitations are imparted to materials for the light-emitting auxiliary layer, and examples thereof include carbazole derivatives and arylamine derivatives. Specifically, examples of the light-emitting auxiliary layer may include NPD (N,N-dinaphthyl-N,N′-diphenyl benzidine), TPD (N,N′-bis-(3-methylphenyl)-N,N′-bis(phenyl)-benzidine), s-TAD, MTDATA (4,4′,4″-Tris(N-3-methylphenyl-N-phenyl-amino)-triphenylamine), and the like, but with no limitations thereto. These may be used solely or in combination.

The light-emitting auxiliary layer may further include a p-type dopant in addition to the above-described material. Any p-type dopant may be used in the present disclosure without particular limitations if it is typically known in in the art. In this regard, a content of the p-type dopant may be appropriately adjusted within a range known in the art, for example, in a range of about 0.5 to 50 parts by weight, based on 100 parts by weight of the hole transport material (100).

The light-emitting auxiliary layer may be formed by a vacuum deposition method, a spin coating method, a casting method, a Langmuir-Blodgett (LB) method, an inkjet printing method, a laser printing method, a laser induced thermal imaging (LITI) method, and the like known in the art, but with no limitations thereto.

### 5) Hole Blocking Layer

The organic EL device (100) of the present disclosure may further include a hole blocking layer (not shown) between the light-emitting layer (320) and the electron transport region (330).

The hole blocking layer (333) functions to block the diffusion of excitons or holes generated in the light-emitting layer (320) into the electron transport layer (331), thus allowing for the improvement of lifespan in the organic EL device.

So long as it is typically known in the art, any material possessing electron transport properties may be used for the hole blocking layer, without any limitation. Examples of the hole blocking layer material include 2,9-dimethyl-4,7-diphenyl-1,10-phenantroline (BCP) and bis(2-methyl-8-quinolinolato) (4-phenyl-phenolato) aluminum (III) (BAlq).

The hole blocking layer can be formed by a vacuum deposition method, a spin coating method, a casting method, a Langmuir-Blodgett (LB) method, an inkjet printing method, a laser printing method, or a laser induced thermal imaging (LITI) method, but with no limitations.

### (4) Capping Layer

Optionally, the organic EL device (100) of the present disclosure may further include a capping layer (not shown) disposed on the cathode (200).

The capping layer may serve to allow light generated in the organic layer to be efficiently emitted to the outside while protecting the organic EL device.

The capping layer may include at least one of tris-8-hydroxyquinoline aluminum (Alq₃), ZnSe, 2,5-bis(6′-(2′,2″-bipyridyl))-1,1-dimethyl-3,4-diphenylsilole, 4′-bis[N-(1-napthyl)-N-phenyl-amino] biphenyl (α-NPD), N,N′-diphenyl-N,N′-bis(3-methylphenyl)-1,1′-biphenyl-4,4′-diamine (TPD), and 1,1′-bis(di-4-tolylaminophenyl) cyclohexane (TAPC). The material for forming such a capping layer is inexpensive as compared to materials of other layers of the organic EL device.

The capping layer may be a single layer, but may include two or more layers having different refractive indices so that the light undergoes a change in refractive index gradually changes while passing through the two or more layers.

The capping layer may be prepared by a conventional method known in the art, and for example, various methods such as a vacuum deposition method, a spin coating method, a casting method, or a Langmuir-Blodgett (LB) method may be used.

As such, the organic EL device according to the present disclosure has a structure in which the anode (100), the organic layer (300) and the cathode (200) are sequentially stacked. In some cases, an insulating layer (not shown) or an adhesive layer (not shown) may be further included between the anode (100) and the organic layer (300) or between the cathode (200) and the organic layer (300). The organic EL device of the present disclosure may have excellent lifespan characteristics because a half-life time of initial brightness is increased while maintaining maximum luminous efficiency when voltage and current are applied.

The organic EL device of the present disclosure described above may be prepared according to a conventional method known in the art. For example, after vacuum deposition of an anode material on a substrate, a hole transport region material, a light-emitting layer material, an electron transport region material, and a cathode material may be vacuum-deposited on the anode, and thus an organic EL device may be manufactured.

A better understanding of the present disclosure may be obtained through the following examples which are set forth to illustrate, but are not to be construed to limit, the present disclosure.

### REFERENCE EXAMPLE

All synthesis reactions were carried out in dry N₂ atmospheres. All solvents s were distilled in sodium-benzophenone under nitrogen before use. Glass wares, syringes, magnetic stirrers, and needles were dried for 4 hours in a convection oven. The reactions were monitored using thin layer chromatography (TLC; Merck Co.). The spots developed on the TLC were identified under UV light at wavelengths of 254 or 365 nm. Column chromatography was performed on Silica gel 60 G (particle size: 5-40 μm; Merck Co.). The synthesized compounds were characterized using ¹H-NMR, ¹³C-NMR spectrometer, elemental analyzer, and high-resolution mass spectrometry (HR-MS). The ¹H-NMR spectrum was recorded on a Varian Mercury 300 (operating at 300.1 MHz), and the ¹³C-NMR spectrum was recorded at KBSI Ochang Center using Bruker Avance II 400 or Avance III HD 700 MHz spectrometers (operating at 100 or 176.1 MHz). HR-MS analysis and elemental analysis were conducted using LC/MS/MSn (n=10) spectrometry (Thermo Fisher Scientific, LCQ Fleet Hyperbolic Ion Trap MS/MSn Spectrometer) and Thermo Scientific FLASH EA-2000 Organic Elemental Analyzer, respectively. The melting points (mp) were recorded on a BuChi B540 apparatus (BuChi Labortechnik AG, Flawil, Switzerland) and were uncorrected. Absorption and emission spectra at room temperature (RT) were recorded using UV-Vis spectrophotometry (Agilent, Cary-5000) and fluorimetry (Varian, Cary Eclipse), respectively. Iridium (III) chloride hydrate was purchased from Sigma-Aldrich and was used without further purification. The fac-/mer-Ir(C\hat{ }C^{H})₃ was synthesized according to previously reported methods

### PREPARATION EXAMPLE

### Synthesis of Ligand

### [Preparation Example 1]—Synthesis of 3-Methyl-1-o-tolyl-1H-imidazol-3-ium iodide ([HC\hat{ }C^{Me}]⁺)

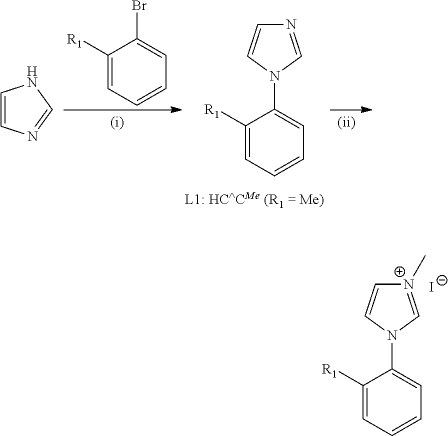

The methylated phenylimidazole ligand (L1) HC\hat{ }C^{Me} was obtained through the Ullmann cross-coupling reaction between 1H-imidazole and 1-bromo-2-methylbenzene, followed by methylation with CH₃I. In this regard, HC\hat{ }C^{Me} was refluxed for 12 hours, filtered, and washed with a chilled organic solvent to synthesize the ligand ([HC\hat{ }C^{Me}]⁺) as a white salt. Details are given as follows.

A solution of 1H-imidazole (7.96 g, 117 mmol), 1-bromo-2-methylbenzene (5.00 g, 29.2 mmol), CuI (1.11 g, 20 mol %), and K₂CO₃ (8.08 g, 58.5 mmol) in DMF (100 mL) was refluxed at 180° C. for 72 hours under a N₂ atmosphere. The reaction mixture was quenched with H₂O, and the product was extracted with CH₂Cl₂ (3×150 mL) and dried over MgSO₄, and then the solvent was evaporated under reduced pressure. The crude product was used in the next reaction without further purification. A mixture of HC\hat{ }C^{Me} (5.00 g) and CH₃I (20.0 g) in THE solvent (100 mL) was refluxed for 12 hours under a N₂ atmosphere. After cooling to room temperature, THF (100 mL) was added, resulting in a white precipitate. The white precipitate was filtered off and washed with cold THE and n-hexane. The resulting white solid was dried in a vacuum oven for 6 hours, and the pure product was obtained in quantitative yield. [mp 139.6-141.2° C.; ¹H-NMR (300.1 MHZ, DMSO-d₆): δ_{H} 9.45 (s, 1H), 8.05 (s, 1H), 7.96 (s, 1H), (7.55-7.46) (m, 4H), 3.96 (s, 3H), 2.23 (s, 3H); ¹³C-NMR (100.6 MHZ, CDCl₃) δ 136.65, 133.32, 133.00, 131.78, 130.87, 127.47, 126.09, 124.35, 123.01, 37.48, 17.92; ESI-MS (m/z): calcd. for C₁₁H₁₃N₂⁺: 173.1073, Found [M−I]⁺: 173.1212; Elemental analysis result (%): C 44.13, H 4.37, N 9.30 (Calcd (%): C 44.02, H 4.37, N 9.33)]

### [Preparation Example 2]—Synthesis of 1-(biphenyl-2-yl)-3-methyl-1H-imidazol-3-ium iodide ([HC\hat{ }C^{Ph}]⁺)

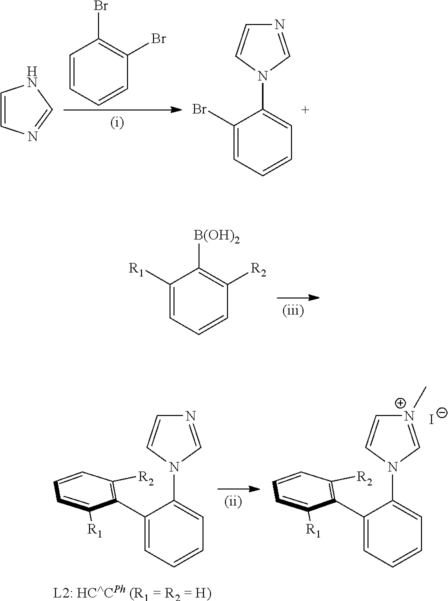

The mono-brominated 1-(2-bromophenyl)-1H-imidazole precursor was obtained through the Ullmann cross-coupling reaction between 1H-imidazole and 1,2-dibromobenzene, followed by Suzuki-Miyaura coupling reaction between the 1-(2-bromophenyl)-1H-imidazole and phenylboronic acid to derive an arylated phenylimidazole ligand (L2), HC\hat{ }C^{Ph}. Subsequently, methylation of HC\hat{ }C^{Ph} with CH₃I was performed by refluxing for 12 hours, filtering at room temperature, and washing with cold organic solvent to afford the ligand ([HC\hat{ }C^{Ph}]⁺) as a white salt. Details are given as follows.

A solution of 1-(2-bromophenyl)-1H-imidazole (5.00 g, 22.4 mmol), phenylboronic acid (3.01 g, 24.7 mmol), Pd₂(dba)₃ (1.03 g, 5 mol %), SPhos (0.92 g, 2.24 mmol), and K₂CO₃ (15.5 g, 112.1 mmol) in CH₃CN/H₂O (3:1, v/v) (100 mL) was refluxed at 110° Cl for 16 hours under a N₂ atmosphere. The reaction mixture was quenched with H₂O, and the product was extracted with CH₂Cl₂ (3×150 mL) and dried over MgSO₄, and then the solvent was evaporated at a reduced pressure. The crude product was used in the next reaction without further purification. A mixture of HC\hat{ }C^{Ph} (5.60 g) and CH₃I (16.0 g) in THE solvent (100 mL) was refluxed for 12 hours under a N₂ atmosphere. After cooling to room temperature, THF (100 mL) was added, resulting in a white precipitate. The white precipitate was filtered off and washed with cold THE and n-hexane. The resulting white solid was dried in a vacuum oven for 6 hours, and the pure product was obtained in quantitative yield. [mp 177.6-178.1° C.; ¹H-NMR (300.1 MHZ, DMSO-d₆): δ_{H} 9.35 (s, 1H), (7.74-7.37) (m, 6H), 7.38 (d, J=1.8 Hz, 3H), (7.23-7.20) (m, 2H), 3.85 (s, 3H); ¹³C-NMR (100.6 MHz, CDCl₃) δ_{C} 137.27, 137.24, 135.98, 132.09, 131.75, 131.15, 129.61, 129.23, 128.60, 128.48, 126.52, 123.48, 123.21, 37. 70; ESI-MS (m/z): calcd. for C₁₆H₁₅N₂⁺: 235.1230, Found [M−I]⁺: 235.1233; Elemental analysis result (%): C 53.15, H 4.16, N 7.73 (Calcd (%): C 53.06, H 4.17, N 7.73).

### [Preparation Example 3]—Synthesis of 3-Methyl-1-(2′-methylbiphenyl-2-yl)-1H-imidazol-3-ium iodide ([HC\hat{ }C^{MePh}]⁺)

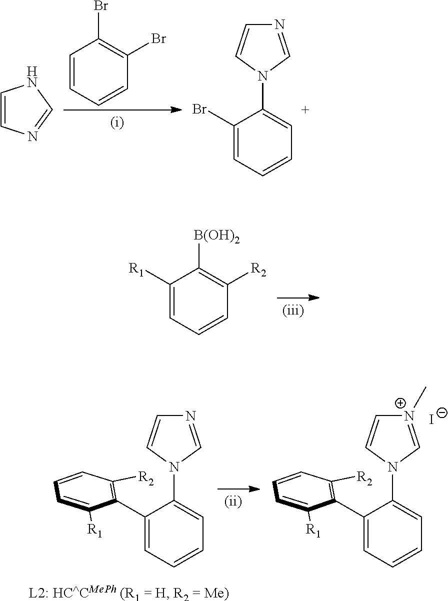

The target ligand was synthesized in the same manner as in Preparation Example 2 (for synthesis of [HC\hat{ }C^{Ph}]⁺), with the exception of using o-tolylboronic acid (3.35 g, 24.7 mmol) instead of phenylboronic acid (3.01 g, 24.7 mmol) [mp 173.2-174.7° C.; ¹H-NMR (300.1 MHZ, DMSO-d₆): δ_{H} 9.33 (s, 1H), (7.77-7.69) (m, 4H), (7.56-7.51) (m, 2H), (7.26-7.11) (m, 4H), 3.82 (s, 3H), 2.02 (s, 3H); ¹³C-NMR (100.6 MHz, CDCl₃) δ_{C} 136.98, 136.52, 135.62, 135.35, 132.64, 131.91, 130.80, 130.69, 129.77, 129.44, 128.98, 126.50, 126.00, 123.40, 122.66, 37.59, 20.00; ESI-MS (m/z): calcd. for C₁₇H₁₇N₂⁺ 249.1386, Found [M−I]⁺: 249.1389; Elemental analysis result (%): C 53.97, H 4.57, N 7.46 (Calcd (%): C 54.27, H 4.55, N 7.45)].

### [Preparation Example 4]—Synthesis of 1-(2′,6′-Dimethylbiphenyl-2-yl)-3-methyl-1H-imidazol-3-ium iodide ([HC\hat{ }C^{diMePh}]⁺)

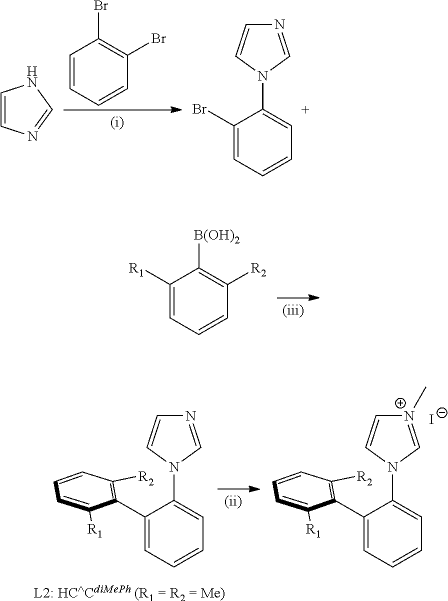

The target ligand was synthesized in the same manner as in Preparation Example 2 (for synthesis of [HC\hat{ }C^{Ph}]⁺), with the exception of using 2,6-dimethylphenylboronic acid (3.70 g, 24.7 mmol) instead of phenylboronic acid (3.01 g, 24.7 mmol) [mp 191.0-192.5° C.; ¹H-NMR (300.1 MHZ, DMSO-d₆): δ_{H} 9.23 (s, 1H), (7.78-7.71) (m, 3H), 7.68 (s, 1H), 7.44 (d, J=7.5 Hz, 1H), 7.40 (s, 1H), 7.19 (t, J=7.8 Hz, 1H), 7.10 (d, J=7.5 Hz, 2H), 3.81 (s, 3H), 1.92 (s, 6H); ¹³C-NMR (100.6 MHz, CDCl₃) δ_{C} 136.88, 135.96, 135.17, 135.05, 132.62, 131.81, 131.14, 129.97, 128.88, 128.13, 126.08, 123.41, 122.15, 37.67, 20.72; ESI-MS (m/z): calcd. for C₁₈H₁₉N₂⁺: 263.1543, Found [M−I]⁺: 263.1546; Elemental analysis result (%): C 55.43, H 4.92, N 7.75 (Calcd (%): C 55.40, H 4.91, N 7.78)].

### SYNTHESIS EXAMPLE

### Synthesis of Ir Complex

### [Comparative Synthesis Example 1]—Synthesis of fac-Ir(C\hat{ }C^{Me})₃ and mer-Ir(C\hat{ }C^{Me})₃

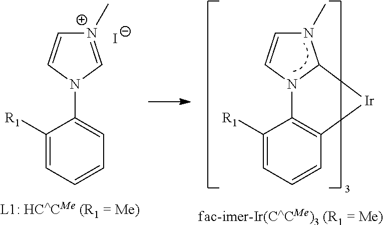

A solution of [HC\hat{ }C^{Me}]⁺ (3.00 g, 10 mmol) synthesized in Preparation Example 1, Ag₂CO₃ (1.38 g, 5.00 mmol), Na₂CO₃ (0.53 g, 5.00 mmol), and IrCl₃·xH₂O (0.88 g, 2.50 mmol) in 2-ethoxyethanol (100 mL) was reflexed for 72 hours in N₂ atmosphere. After being cooled to room temperature, the reaction mixture was added to water. The precipitate thus formed was collected by filtration and washed with H₂O and n-hexane. Gray crude powder was coated with silica and purified by column chromatography using CH₂Cl₂/ethyl acetate/n-hexane (1:1:4, v/v) as a eluent, to afford the title compounds as off-white solids [fac-Ir(C\hat{ }C^{Me})₃ (R_{f}=0.4) and mer-Ir(C\hat{ }C^{Me})₃ (R_{f}=0.6)].

\textcircled{1} fac-Ir(C\hat{ }C^{Me})₃. (0.85 g, yield 12%); mp not detected; ¹H-NMR (300.1 MHZ, DMSO-d₆): δ_{H} 7.85 (s, 3H), 7.13 (s, 3H), (6.53-6.50) (m, 3H), (6.35-6.30) (m, 6H), 2.95 (s, 9H), 2.54 (s, 9H); ¹³C-NMR (176.1 MHZ, DMSO-d₆) δ_{C} 177.11, 152.54, 146.29, 135.21, 124.13, 123.42, 120.58, 119.73, 117.60, 35.93, 21.72; ESI-MS (m/z): calcd. for C₃₃H₃₃IrN₆: 706.2396, Found [M]⁺: 706.2439; Elemental analysis result (%): C 56.01, H 4.69, N 11.55 (Calcd (%): C 56.15, H 4.71, N 11.91).

\textcircled{2} mer-Ir(C\hat{ }C^{Me})₃. (2.18 g, yield 31%); mp 391.1-392.7° C.; ¹H-NMR (300.1 MHZ, CD₂Cl₂-d₂): δ_{H} 7.87 (d, 1H), 7.81 (d, J=1.8 Hz 1H), 7.75 (d, J=2.4 Hz 1H), 6.79 (d, J=2.7 Hz, 1H), 6.77 (d, J=2.4 Hz, 1H), 6.69 (d, J=1.5 Hz, 1H), (6.63-6.46) (m, 9H), 3.03 (s, 3H), 3.00 (s, 3H), 2.94 (s, 3H), 2.61 (s, 3H), 2.59 (s, 6H); ¹³C-NMR (176.1 MHz, DMSO-d₆) δ_{C} 177.15, 175.36, 174.53, 154.18, 153.15, 152.26, 147.23, 146.69, 145.92, 137.94, 137.55, 135.31, 124.54, 124.30, 124.15, 124.03, 123.97, 123.94, 120.65, 120.59, 119.94, 119.88, 119.70, 119.35, 118.10, 118.00, 117.95, 37.42, 37.14, 36.10, 22.29, 22.01, 21.91; ESI-MS (m/z): calcd. for C₃₃H₃₃IrN₆: 706.2396, Found [M]⁺: 706.2416; Elemental analysis result (%): C 56.14, H 4.74, N 11.92 (Calcd (%): C 56.15, H 4.71, N 11.91).

### [Comparative Synthesis Example 2]—Synthesis of fac-Ir(C\hat{ }C^{Ph})₃ and mer-Ir(C\hat{ }C^{Ph})₃

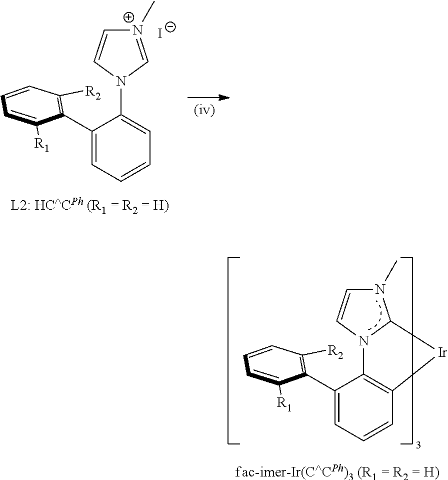

The target compounds fac-Ir(C\hat{ }C^{Ph})₃ and mer-Ir(C\hat{ }C^{Ph})₃ were synthesized in the same manner as in Comparative Synthesis Example 1, with the exception of using 2-ethoxyethanol (80 mL), [HC\hat{ }C^{Ph}]⁺ synthesized in Preparation Example 2 (3.00 g, 8.28 mmol), Ag₂CO₃ (1.14 g, 4.14 mmol), Na₂CO₃ (0.44 g, 4.14 mmol), and IrCl₃·xH₂O (0.73 g, 2.07 mmol). Purification silica through gel column chromatography using CH₂Cl₂/ethyl acetate/n-hexane (1:1:4, v/v) as an eluent afforded the compounds as off-white solids [fac-Ir(C\hat{ }C^{Ph})₃ (R_{f}=0.2) and mer-Ir(C\hat{ }C^{Ph})₃ (R_{f}=0.5)].

\textcircled{1} fac-Ir(C\hat{ }C^{Ph})₃. (0.81 g, yield 11%); mp 377.3-378.8° C.; ¹H-NMR (300.1 MHZ, DMSO-d₆): δ_{H} (7.50-7.40) (m, 9H), 7.31 (d, J=6.6 Hz, 6H), 6.86 (s, 3H), (6.65-6.58) (m, 9H), 6.03 (s, 3H), 2.94 (s, 9H); ¹³C-NMR (100.6 MHZ, CDCl₃) δ_{C} 177.92, 152.50, 144.61, 142.37, 136.91, 130.16, 129.21, 128.33, 128.29, 127.12, 126.84, 123.87, 123.48, 118.52, 118.43, 36.44; ESI-MS (m/z): calcd. for C₄₈H₃₉IrN₆: 892.2865, Found [M]⁺: 892.2868; Elemental analysis result (%): C 64.70, H 4.44, N 9.39 (Calcd (%): C 64.63, H 4.41, N 9.42).

\textcircled{2} mer-Ir (C\hat{ }C^{Ph})₃. (2.07 g, yield 28%); mp 329.1-330.6° C.; ¹H-NMR (300.1 MHZ, DMSO-d₆): δ_{H} (7.52-7.40) (m, 9H), (7.36-7.29) (m, 4H), (7.23-7.21) (m, 2H), 6.91 (d, J=2.7 Hz, 1H), 6.87 (d, J=1.8 Hz, 1H), (6.82-6.79) (m, 2H), (6.62-6.51) (m, 7H), (6.43-6.39) (m, 1H), 6.11 (d, J=1.8 Hz, 1H), 6.08 (d, J=2.7 Hz, 1H), 6.02 (d, J=2.7 Hz, 1H), 3.01 (s, 3H), 2.98 (s, 3H), 2.96 (s, 3H); ¹³C-NMR (176.1 MHZ, DMSO-d₆) δ_{C} 176.68, 173.74, 173.48, 154.62, 152.39, 150.82, 144.96, 144.39, 143.68, 141.74, 141.59, 141.53, 137.95, 137.68, 136.00, 129.36, 129.29, 129.15, 129.02, 128.90, 128.85, 128.80, 128.75, 128.63, 128.44, 128.42, 127.28, 127.25, 127.01, 126.91, 126.71, 123.89, 123.48, 123.04, 122.53, 122.44, 120.68, 120.52, 120.22, 117.46, 117.40, 117.02, 36.66, 36.39, 35.36; ESI-MS (m/z): calcd. for C₄₈H₃₉IrN₆: 892.2865, Found [M]⁺: 892.2612; Elemental analysis result (%): C 64.34, H 4.39, N 9.44 (Calcd (%): C 64.63, H 4.41, N 9.42).

### [Comparative Synthesis Example 3]—Synthesis of fac-Ir(C\hat{ }C^{H})₃ and mer-Ir(C\hat{ }C^{H})₃

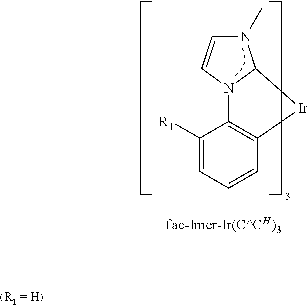

The target compounds fac-Ir(C\hat{ }C^{H})₃ and mer-Ir(C\hat{ }C^{H})₃ were synthesized as described previously (Sajoto, T.; Djurovich, P. I.; Tamayo, A.; Yousufuddin, M.; Bau, R.; Thompson, M. E.; Holmes, R. J.; Forrest, S. R. Blue and near-UV phosphorescence from iridium complexes with cyclometalated pyrazolyl or N-heterocyclic carbene ligands. Inorg. Chem. 2005, 44, 7992-8003.).

### [Synthesis Example 1]—Synthesis of fac-Ir(C\hat{ }C^{MePh})₃ and mer-Ir(C\hat{ }C^{MePh})₃

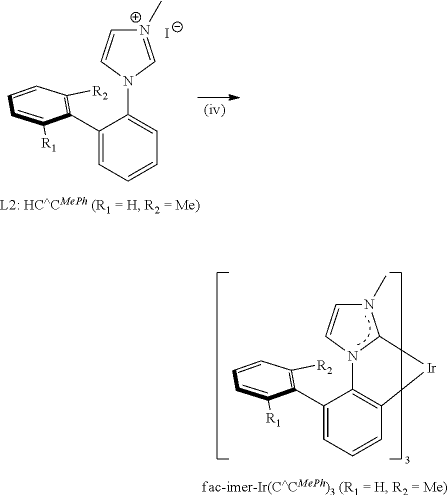

The target compounds fac-Ir(C\hat{ }C^{MePh})₃ and mer-Ir(C\hat{ }C^{MePh})₃ were synthesized in the same manner as in Comparative Synthesis Example 1, with the exception of using 2-ethoxyethanol (70 mL), [HC\hat{ }C^{MePh}]⁺ synthesized in Preparation Example 3 (2.50 g, 6.64 mmol), Ag₂CO₃ (0.92 g, 3.32 mmol), Na₂CO₃ (0.35 g, 3.32 mmol), and IrCl₃·xH₂O (0.59 g, 1.66 mmol). Purification through silica gel column chromatography using CH₂Cl₂/ethyl acetate/n-hexane (1:1:4, v/v) as an eluent afforded the target compounds as off-white solids [fac-Ir(C\hat{ }C^{MePh})₃ (R_{f}=0.4) and mer-Ir(C\hat{ }C^{MePh})₃ (R_{f}=0.7)].

\textcircled{1} fac-Ir(C\hat{ }C^{MePh})₃. (0.50 g, yield 8%); mp 379.9-380.4° C.; ¹H-NMR (300.1 MHZ, DMSO-d₆): δ_{H} (7.33-7.18) (m, 12H), 6.84 (s, 3H), (6. 63-6.50) (m, 9H), (5.87-5.85) (m, 3H), (2.95-2.84) (m, 9H), (1.97-1.95) (m, 9H); ¹³C-NMR (176.1 MHz, CDCl₃) δ_{C} 177.80, 153.01, 145.03, 141.80, 136.86, 136.37, 130.19, 129.63, 128.15, 126.70, 126.02, 123.88, 122.57, 120.80, 116.36, 36.26, 20.02; ESI-MS (m/z): calcd. for C₅₁H₄₅IrN₆: 934.3335, Found [M]⁺: 934.3323; Elemental analysis result (%): C 65.55, H 4.83, N 8.95 (Calcd (%): C 65.57, H 4.86, N 9.00).

\textcircled{2} mer-Ir(C\hat{ }C^{MePh})₃. (1.49 g, yield 24%); mp 232.9-233.5° C.; ¹H-NMR (300.1 MHZ, DMSO-d₆): δ_{H} (7.33-7.11) (m, 12H), (6.89-6.82) (m, 3H), (6.60-6.43) (m, 9H), (5.96-5.87) (m, 3H), (3.02-2.85) (m, 9H), (1.98-1.91) (m, 9H); ¹³C-NMR (176.12 MHZ, DMSO-d₆) δ_{C} 176.64, 173.81, 173.57, 154.45, 152.38, 150.45, 144.87, 144.30, 143.69, 141.28, 141.15, 141.13, 138.19, 137.70, 135.91, 129.84, 129.74, 129.67, 129.58, 129.48, 129.45, 129.40, 129.35, 129.29, 129.23, 129.08, 127.71, 126.36, 126.27, 126.22, 126.13, 125.95, 125.71, 125.55, 124.38, 124.22, 123.75, 123.09, 122.99, 120.96, 120.87, 120.55, 116.29, 116.20, 115.97 36.65, 36.57, 35.19, 19.91 , 19.58 , 19.53; ESI-MS (m/z): calcd. for C₅₁H₄₅IrN₆: 934.3335, Found [M]⁺: 934.3413); Elemental analysis result (%): C 65.52, H 4.85, N 8.96 (Calcd (%): C 65.57, H 4.86, N 9.00).

### [Synthesis Example 2]—Synthesis of fac-Ir(C\hat{ }C^{diMePh})₃ and mer-Ir(C\hat{ }C^{diMePh})₃

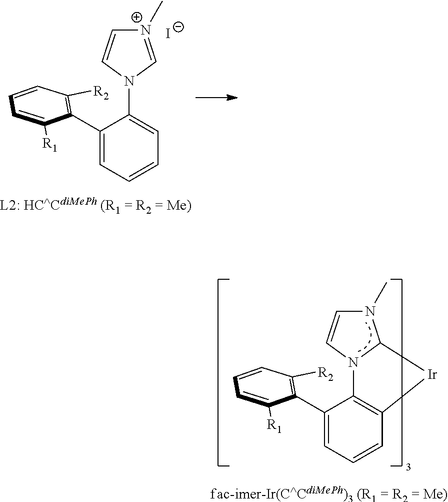

The target compounds fac-Ir(C\hat{ }C^{diMePh})₃ and mer-Ir(C\hat{ }C^{diMePh})₃ were synthesized in the same manner as in Comparative Synthesis Example 1, with the exception of using 2-ethoxyethanol (70 mL), [HC\hat{ }C^{diMePh}]⁺ synthesized in Preparation Example 4 (2.80 g, 7.17 mmol), Ag₂CO₃ (0.99 g, 3.59 mmol), Na₂CO₃ (0.38 g, 3.59 mmol), and IrCl₃·xH₂O (0.63 g, 1.79 mmol). Purification through silica gel column chromatography using CH₂Cl₂/ethyl acetate/n-hexane (1:1:3, v/v) as an eluent afforded the target compounds as off-white solids [fac-Ir(C\hat{ }C^{diMePh})₃ (R_{f}=0.4) and mer-Ir(C\hat{ }C^{diMePh})₃ (R_{f}=0.6)].

\textcircled{1} fac-Ir(C\hat{ }C^{diMePh})₃. (0.63 g, yield 9%); mp 382.2-383.7° C.; ¹H-NMR (300.1 MHz, DMSO-d₆): δ_{H} (7.27-7.17) (m, 9H), 6.81 (s, 3H), 6.64 (d, J=7.2 Hz, 3H), 6.55 (t, J=7.2 Hz, 3H), 6.42 (d, J=7.2 Hz, 3H), 5.79 (s, 3H), 2.89 (s, 9H), 1.98 (s, 9H), 1.91 (s, 9H); ¹³C-NMR (100.6 MHZ, CDCl₃) δ 178.90, 152.13, 144.29, 141.39, 137.66, 136.50, 136.24, 128.06, 127.50, 126.99, 124.60, 121.88, 119.50, 118.91, 116.84, 36.34, 20.59; ESI-MS (m/z): calcd. for C₅₄H₅₁IrN₆: 976.3804, Found [M]⁺: 976.3821; Elemental analysis result (%): C 66.80, H 5.27, N 8.54 (Calcd (%): C 66.44, H 5.27, N 8.61).

\textcircled{2} mer-Ir(C\hat{ }C^{diMePh})₃. (1.47 g, yield 21%); mp 299.6-301.2° C.; ¹H-NMR (300.1 MHz, DMSO-d₆): δ_{H} (7.24-7.17) (m, 9H), 6.91 (d, J=7.5 Hz, 1H), (6.83-6.80) (m, 3H), 6.63 (t, J=6.9 Hz, 1H), (6.58-6.50) (m, 3H), 6.36 (d, J=7.2 Hz, 3H), 6.30 (d, J=7.2 Hz, 1H), (5.89-5.88) (m, 2H), 5.79 (s, 1H), 3.05 (s, 3H), 2.95 (s, 3H), 2.88 (s, 3H), 1.99 (s, 3H), 1.93 (s, 3H), 1.91 (s, 3H) 1.85 (s, 3H), 1.83 (s, 3H), 1.78 (s, 3H); ¹³C-NMR (100.6 MHz, CDCl₃) δ_{C} 178.90, 177.36, 175.92, 174.63, 154.89, 152.14, 144.90, 144.28, 141.38, 139.12, 138.38, 137.74, 137.66, 137.51, 137.05, 136.80, 136.65, 136.50, 136.22, 136.13, 135.76, 127.51, 127.45, 127.34, 127.18, 127.13, 127.01, 124.80, 124.68, 124.59, 124.46, 124.42, 124.13, 121.87, 121.65, 121.32, 121.16, 121.06, 119.83, 119.50, 119.08, 118.90, 116.84, 116.68, 37.58, 37.29, 36.41, 35.74, 20.92, 20.86, 20.69, 20.65, 20.46, 20.38; ESI-MS (m/z): calcd. for C₅₄H₅₁IrN₆: 976.3804, Found [M]⁺: 976.3954; Elemental analysis result (%): C 66.83, H 5.28, N 8.66 (Calcd (%): C 66.44, H 5.02, N 8.61).

### Synthesis Example 3

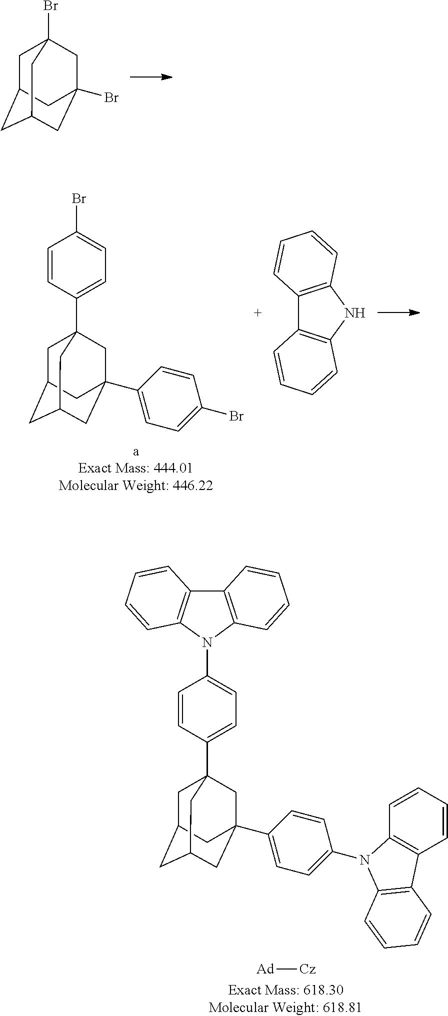

The precursor Compound a was synthesized (yield: ca. 80%).

¹H-NMR (300 MHZ, CDCl₃) for Compound a: 7.46-7.42 (d, J=11.4 Hz, 4H), 7.28-7.25 (d, J=6.9 Hz, 4H), 2.32 (s, 1H), 1.96 (s, 6H), 1.92 (s, 6H), 1.78 (s, 1H).

Compound a and carbazole were subjected to coupling reaction in the presence of CuI to synthesize Ad-Cz. The reaction mixture was developed/separated through silica column using ether: CH₂Cl₂ solvent to afford the target compound (yield: 25%). Subsequently, the compound Ad-Cz was purified by sublimation for deposition and was identified to have a purity of 99.9% as analyzed by HPLC (purification yield: 50%).

¹H-NMR of compound Ad-Cz (300 MHZ, CDCl₃): δ 8.18-8.13 (m, 4H), 7.68-7.49 (m, 6H), 7.43-7.36 (m, 10H), 7.32-7.27 (m, 4H), 2.42 (t, 1H), 2.20 (t, J=11.1 Hz, 6H), 2.09 (t, J=12.3 Hz, 6H), 1.87 (t, J=14.1 Hz, 1H) (Figure S2). ¹³C-NMR (75.47 MHz, CDCl₃): δ 29.65, 35.89, 37.77, 42.32 49.31, 109.94, 120.45, 123.38, 124.21, 125.94, 126.05, 126.91, 129.74, 141.13, 149.72, 152.79. ESI-MS (m/z): calcd. for C₄₆H₃₈N₂: 618.3035, Found [M]⁺: 618.4415.

### [Experimental Example 1]—Characteristics of Ir-Based Complexes

The Ir complexes synthesized in Comparative Synthesis Examples 1-3 and Synthesis Examples 1-2 were measured for crystal structure, photophysical properties, and electrochemical properties, and calculated for DFT (Density Functional Theory). The results are summarized in Tables 1-6 and depicted in FIGS. 2 to 11.

### (1) Crystal Structures

FIG. 2 is ORTEP drawings accounting for the structures of fac-Ir(C\hat{ }C^{Ph})₃ of Comparative Synthesis Example 2 and fac-Ir(C\hat{ }C^{diMePh})₃ of Synthesis Example, as analyzed by single crystal X-ray diffraction. The analysis data are summarized by Table 1, below.

TABLE 1

| | | fac-Ir(C\hat{ }C^{Ph})₃ | | fac-Ir (C\hat{ }C^{diMePh})₃ | |
|---|---|---|---|---|---|
| Parameters | | Selected value | Average | Selected value | Average |
| Bond length | Ir-C_{carbene} | 2.033(4) | 2.037 | 2.029(5) | 2.034 |
| (Å) | | 2.041(4) | | 2.037(4) | |
| | | 2.038(4) | | 2.037(4) | |
| | Ir-C_{Ph} | 2.083(4) | 2.089 | 2.078(4) | 2.081 |
| | | 2.090(4) | | 2.081(4) | |
| | | 2.093(4) | | 2.085(5) | |
| Angle | [symbol] C_{carbene}-Ir-C_{Ph} | 77.91(2) | 77.78 | 77.83(2) | 77.76 |
| (° ) | | | | 77.93(2) | |
| | | 78.06(2) | | 77.52(2) | |
| | | 77.36(2) | | | |
| 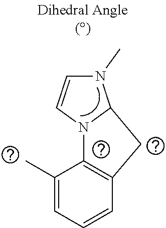 | D1^{a} D2^{b} | 90.0(7) 58.9(7) 66.8(7) 8.1(8) 10.6(8) 15.8(8) | 71.9 11.5 | 94.6(6) 95.2(6) 82.2(7) 3.1(8) 4.8(7) 2.5(8) | 90.7 3.5 |

^{a}D1 means a dihedral angle between the aryl substituent (Ph or diMePh) and the phenyl plane in the coordinated C\hat{ }C ligand.
^{b}D2 means a dihedral angle between the phenyl plane and the imidazole (NHC) ring in the coordinated C\hat{ }C ligand

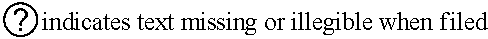

### (2) Photophysical Properties

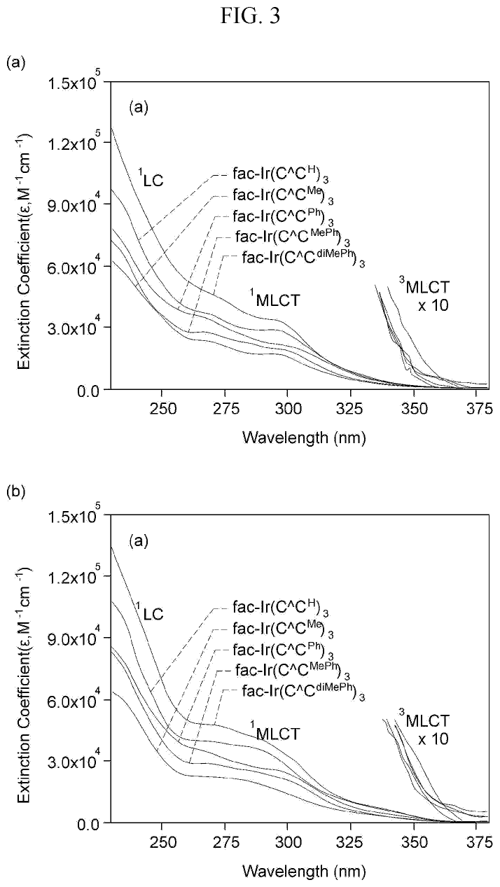

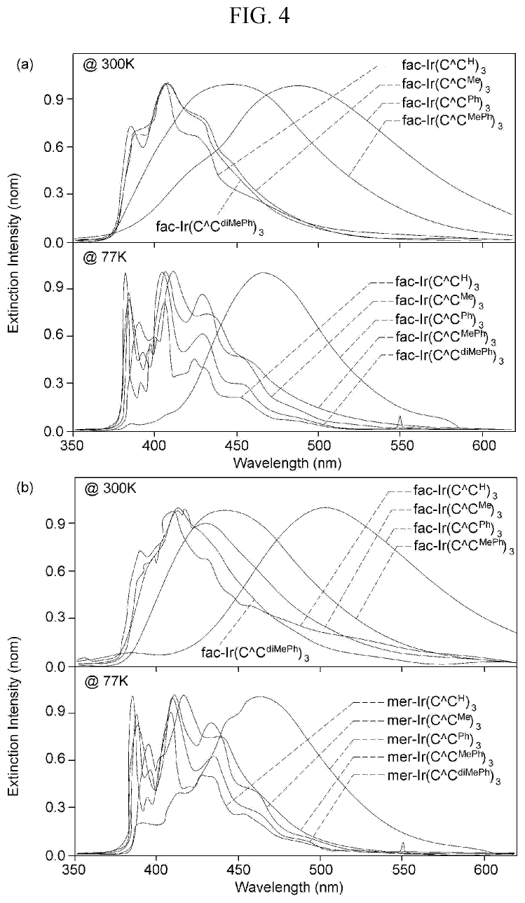

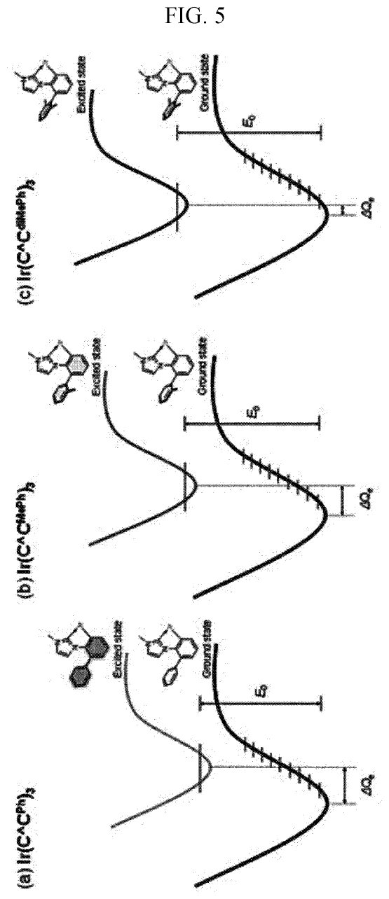

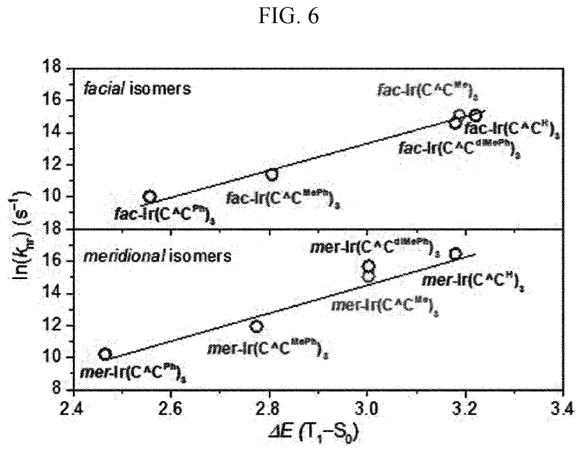

The Ir complexes synthesized in Synthesis Examples 1-2 and Comparative Synthesis Examples 1-3 were measured for steady-state absorption and emission spectra in CH₂Cl₂ solution (300 K) and 2-MeTHF (77 K). The measurements are summarized in Tables 2-4 and depicted in FIGS. 3-4. Additionally, the energy gap (E0) and the relative nuclear displacement influencing parameters of the Ir complexes synthesized in Synthesis Examples 1-2 and Comparative Synthesis Example 2 were identified, with the results displayed in FIG. 5. Moreover, for the natural logarithm of the non-radiative decay of the triplet state in the Ir complexes synthesized in Synthesis Examples 1-2 and Comparative Synthesis Examples 1-3 was depicted against the energy gap of the T₁-S₀ state determined by maximum photoexcitation at 300 K in FIG. 6

TABLE 2

| | at 300K^{a} | | | | | |
|---|---|---|---|---|---|---|
| | Solution | | | | | |
| | | | | Stokes | | |
| | λ [symbol] | τ [symbol] | Φ_{PL} | Shift^{d} | k [symbol] | k [symbol] |
| | [nm] | [μs] | [%] | [cm⁻¹] | [10 [symbol] s⁻¹] | [10 [symbol] s⁻¹] |
| fac-Ir (C\hat{ }C [symbol] )₃ | 385, 406 | 0.28 | 3.5 | 2,844 | 1.25 | 34.46 |
| mer-Ir (C\hat{ }C [symbol] )₃ | 390, 409 | 0.07 | 1.2 | 2,539 | 1.71 | 141.14 |
| fac-Ir (C\hat{ }C^{Me})₃ | 389, 408 | 0.28 | 2.2 | 3,328 | 0.79 | 34.49 |
| mer-Ir (C\hat{ }C^{Me})₃ | 396, 413 | 0.03 | 1.0 | 2,944 | 3.33 | 330.00 |
| fac-Ir (C\hat{ }C^{Ph})₃ | 485 | 39.2 (77%), 7.26 (23%) | 13.1 | 8,404 | 0.03 | 0.22 |
| mer-Ir (C\hat{ }C^{Ph})₃ | 503 | 31.4 (88%), 3.39 (12%) | 13.7 | 7,601 | 0.04 | 0.28 |
| fac-Ir (C\hat{ }C^{MePh})₃ | 442 | 10.1 (87%), 2.21 (13%) | 12.1 | 5,881 | 0.12 | 0.87 |
| mer-Ir (C\hat{ }C^{MePh})₃ | 447 | 5.92 (53%), 2.83 (47%) | 8.6 | 5,422 | 0.15 | 1.54 |
| fac-Ir(C\hat{ }C^{diMePh})₃ | 390, 408 | 0.43 | 6.9 | 3,037 | 1.60 | 21.65 |
| mer-Ir(C\hat{ }C^{diMePh})₃ | 413 | 0.15 | 1.9 | 2,879 | 1.27 | 65.40 |

^{a}Values were measured in an Ar-saturated dichloromethane (CH₂Cl₂) solution (10 μM) at 300K. The absolute quantum yield was measured through the Quantaurus-QY measurement system (λₑₓ = 305 nm) and was integrated over the range of 350-700 nm;
^{d}Strokes shifts were obtained from the following equation: Strokes shift = \dot{ν}a-\dot{ν}f. As there was no clearly identifiable peak in the absorption spectrum, the absorption value (\dot{ν}a) was determined at the edge of the weak absorption tail (350-380 nm) of the Ir complex, which can impart ³MLCT. The position of the absorption edge was determined at the istersection of a straight line adjusted to the right of the absorption shoulder (around 325 nm) and a corrected baseline. \dot{ν}f was determined by the first peak of the luminescence spectrum at 300K [symbol]
indicates data missing or illegible when filed

TABLE 3

at 300K^{a}
Film^{b}

| | λₚ | Φ_{PL} |
|---|---|---|
| | [nm] | [%] |
| fac-Ir(C\hat{ }C^{H})₃ | 385, 405 | 37.0 |
| mer-Ir(C\hat{ }C^{H})₃ | 388, 408 | 26.9 |
| fac-Ir(C\hat{ }C^{Me})₃ | 389, 407 | 28.9 |
| mer-Ir(C\hat{ }C^{Me})₃ | 393, 411 | 31.7 |
| fac-Ir(C\hat{ }C^{Ph})₃ | 483 | 16.7 |
| mer-Ir(C\hat{ }C^{Ph})₃ | 479 | 27.2 |
| fac-Ir(C\hat{ }C^{MePh})₃ | 415 | 17.9 |
| mer-Ir(C\hat{ }C^{MePh})₃ | 415 | 23.8 |
| fac-Ir(C\hat{ }C^{diMePh})₃ | 387, 406 | 60.1 |
| mer-Ir(C\hat{ }C^{diMePh})₃ | 393, 411 | 49.1 |

^{a}Values were measured in an Ar-saturated dichloromethane (CH₂Cl₂) solution (10 μM) at 300K. The absolute quantum yield was measured through the Quantaurus-QY measurement system (λₑₓ = 305 nm) and was integrated over the range of 350-700 nm;
^{b}Films were prepared on melted silica glass substrate (5 wt % Ir(III) complex), using a solution of poly(methylmethacrylate) (PMMA) in toluene.

TABLE 4

| | at 77K^{c} | | | |
|---|---|---|---|---|
| | λₚ | τₚ | Stokes Shift^{d} | |
| | [ nm ] | [os] | [cm⁻¹] | S^{e} |
| fac-Ir(C\hat{ }C^{H})₃ | 382, 405 | 6.64 | 2,228 | 0.80 |
| mer-Ir(C\hat{ }C^{H})₃ | 385, 408 | 7.35 | 1,963 | 0.90 |
| fac-Ir(C\hat{ }C^{Me})₃ | 384, 407 | 7.34 | 2,532 | 1.15 |
| mer-Ir(C\hat{ }C^{Me})₃ | 387, 410 | 7.56 | 2,283 | 1.14 |
| fac-Ir(C\hat{ }C^{Ph})₃ | 466 | 91.6 (73%), 43.8 (27%) | 6,538 | — |
| mer-Ir(C\hat{ }C^{Ph})₃ | 464 | 93.4 (71%), 2.35 (29%) | 5,694 | — |
| fac-Ir(C\hat{ }C^{MePh})₃ | 390, 411 | 5.95 (95%), 22.6 (5%) | 2,738 | 1.49 |
| mer-Ir(C\hat{ }C^{MePh})₃ | 394, 416 | 6.37 (97%), 29.4 (3%) | 2,403 | 1.45 |
| fac-Ir(C\hat{ }C^{diMePh})₃ | 383, 406 | 5.50 | 2,562 | 1.23 |
| mer-Ir(C\hat{ }C^{diMePh})₃ | 387, 410 | 5.86 | 2,185 | 1.22 |

^{c}The values listed are for a 2-MeTHF glassy matrix at 77K;
^{d}Strokes shifts were obtained from the following equation: Strokes shift = \dot{ν}a-\dot{ν}f. As there was no clearly identifiable peak in the absorption spectrum, the absorption value (ba) was determined at the edge of the weak absorption tail (350-380 nm) of the Ir complex, which can impart ³MLCT. The position of the absorption edge was determined at the intersection of a straight line adjusted to the right of the absorption shoulder (around 325 mm) and a corrected baseline. \dot{ν}f was determined by the first peak of the luminescence spectrum at 300K;
^{e}Huang-Rhys factors (S) were determined from the peak heights of the first two features of the 77K luminescence spectrum

### (3) Electrochemical Properties

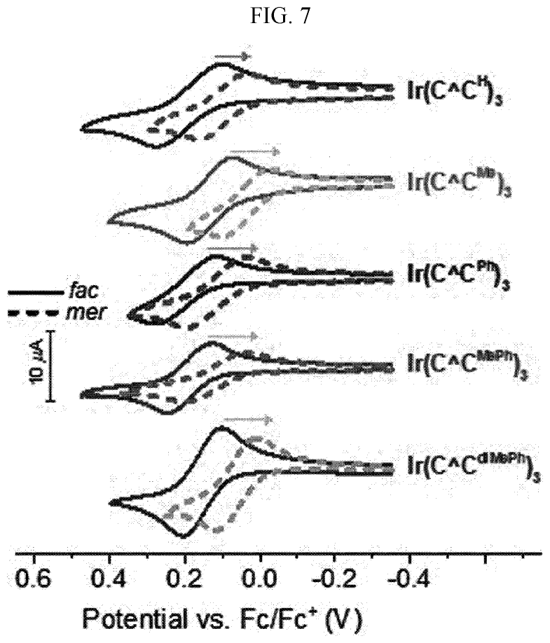

The Ir complexes synthesized in Synthesis Examples 1-2 and Comparative Synthesis Examples 1-3 were measured for HOMO and LUMO energy levels by cyclic voltammetry (CV) (measurement was conducted for the oxidized face in the presence of 0.1 M TBAP in CH₂Cl₂. scan rate: (100) mV/s), and the results are given in FIG. 7 and Table 5.

TABLE 5

| | E_{oz} | E_{LUMO}/E_{HOMO} | E_{g} (exp.) | E_{LUMO}/E_{HOMO} | E_{g} (theo.) |
|---|---|---|---|---|---|
| | [eV]^{a} | [eV] (exp.)^{a} | [eV]^{b} | [eV] (theo.)^{c} | [eV] |
| fac-Ir(C\hat{ }C^{H})₃ | 0.28 | −1.54/−5.08 | 3.54 | 0.14/−4.62 | 4.76 |
| mer-Ir(C\hat{ }C^{H})₃ | 0.16 | −1.50/−4.96 | 3.46 | 0.06/−4.57 | 4.63 |
| fac-Ir(C\hat{ }C^{Me})₃ | 0.19 | −1.43/−4.99 | 3.56 | 0.22/−4.57 | 4.79 |
| mer-Ir(C\hat{ }C^{Me})₃ | 0.10 | −1.40/−4.90 | 3.50 | 0.14/−4.51 | 4.65 |
| fac-Ir(C\hat{ }C^{Ph})₃ | 0.28 | −1.58/−5.08 | 3.50 | −0.19/−4.65 | 4.46 |
| mer-Er(C\hat{ }C^{Ph})₃ | 0.20 | −1.59/−5.00 | 3.41 | −0.32/−4.62 | 4.30 |
| fac-Ir(C\hat{ }C^{MePh})₃ | 0.25 | −1.51/−5.05 | 3.54 | −0.03/−4.67 | 4.64 |
| mer-Ir(C\hat{ }C^{MePh})₃ | 0.20 | −1.55/−5.00 | 3.45 | −0.10/−4.62 | 4.52 |
| fac-Ir(C\hat{ }C^{diMePh})₃ | 0.21 | −1.48/−5.01 | 3.53 | 0.04/−4.70 | 4.74 |
| mes-Ir(C\hat{ }C^{diMePh})₃ | 0.12 | −1.46/−4.92 | 3.46 | −0.05/−4.65 | 4.60 |

^{a}HOMO levels were determined using Equation 1 [E_{HOMO} (eV) = −e(E_{oz}^{peak} ÷ 4.8)] and LUMO levels were determined using Equation 2 [E_{LUMO} (eV) = −e(E_{HOMO}^{peak} + E_{g}^{edge})]
^{b}E_{g}^{edge} values were calculated using the wavelength of absorption band edge onset.
^{c}E_{LUMO}/E_{HOMO}^{peak} [eV] (theo.) values were obtained from DFT calculation

### (4) DFT Calculation

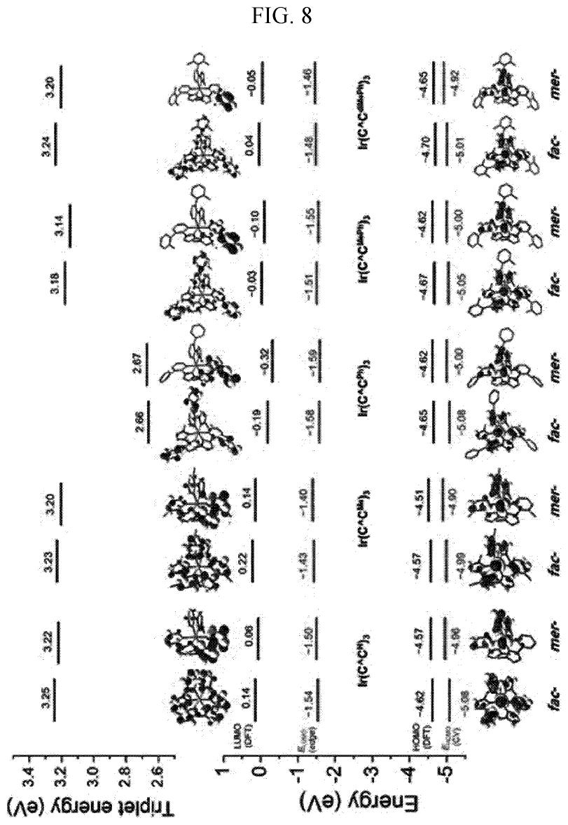

For the Ir complexes synthesized in Synthesis Examples 1-2 and Comparative Synthesis Examples 1-3, DFT calculations (Density Functional Theory calculations) were performed (6-31G basis set for C, H, and N atoms at the B3LYP level; and LANL2DZ basis set for Ir metal in the gas phase). The results are depicted in FIG. 8. In this regard, the ground-state geometric structures of each Ir complex were optimized at the DFT level, and the properties of the exited state were computed using the linear response time-dependent DFT (TD-DFT) software package.

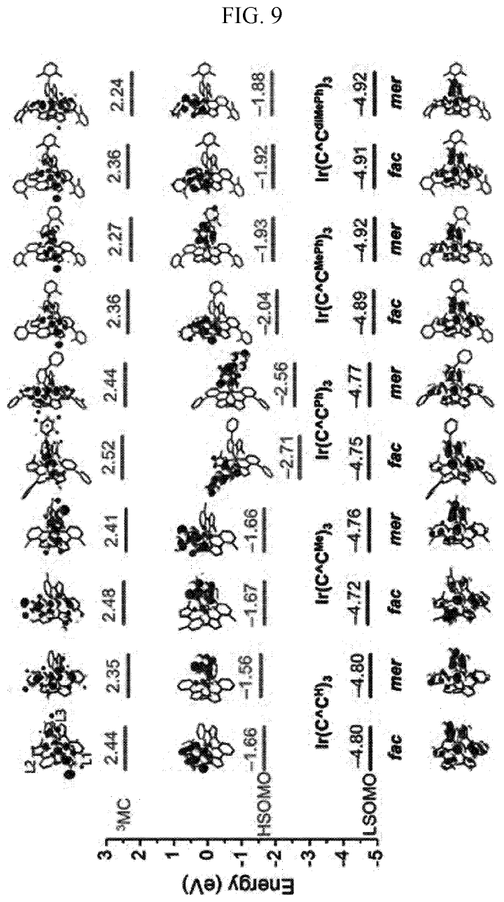

In order to understand the triplet excited-state characteristics of the Ir complexes synthesized in Synthesis Examples 1-2 and Comparative Synthesis Examples 1-3, TD-DFT was performed, and the results are depicted in FIG. 9. For this, the triplet state structures were optimized based on the geometric structures optimized from singlet state DFT calculations.

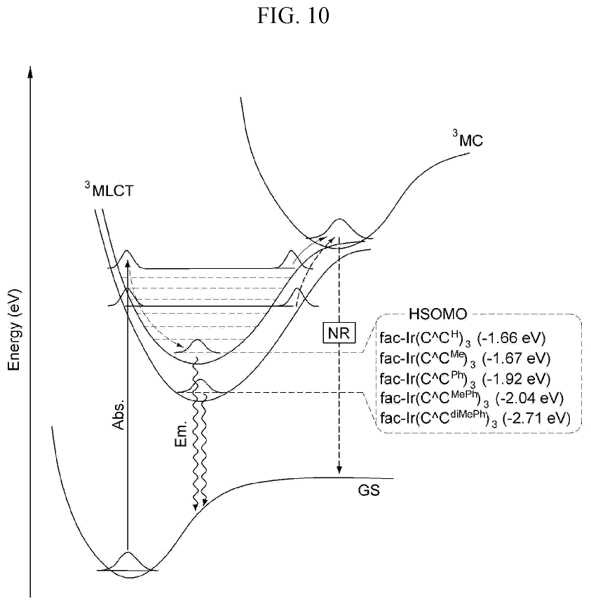

Furthermore, the energy diagram of the Ir complexes synthesized in Synthesis Examples 1-2 and Comparative Synthesis Examples 1-3 is given in FIG. 10, which illustrates the involvement of the ³MC state in the non-radiative pathway from the triplet excited state (HSOMO).

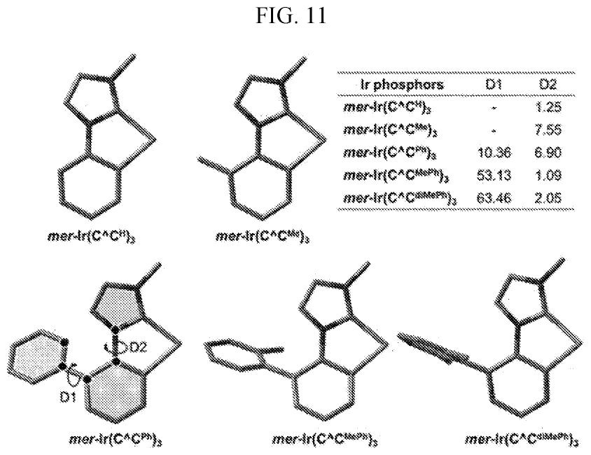

Additionally, the optimized excited-state structures of the meridional Ir complexes synthesized in Synthesis Examples 1-2 and Comparative Synthesis Examples 1-3 were determined through DFT calculations and are depicted in FIG. 11. In FIG. 11, D1 and D2 denote the dihedral angles of the coordinated C\hat{ }CR ligands (R═H, Me, Ph, MePh, and diMePh).

### Example 1

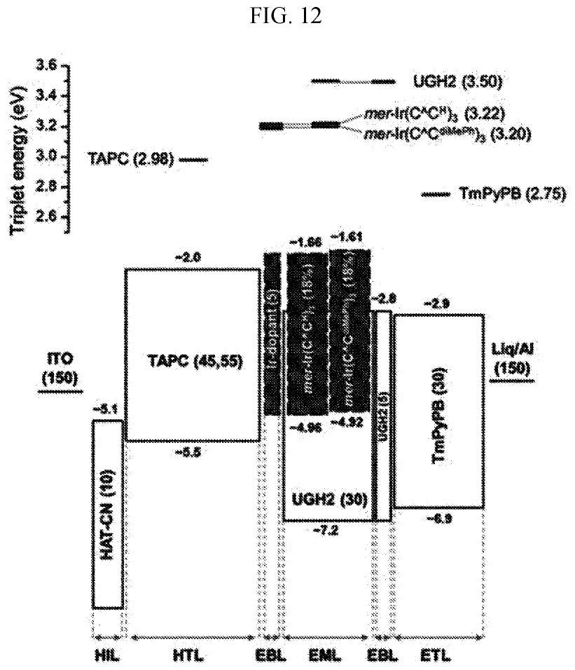

The mer-Ir(C\hat{ }C^{diMePh})₃ synthesized in Synthesis Example 2 was used to fabricate a blue phosphorescent OLED with the structure of ITO (150 nm, anode)/HAT-CN (10 nm)/TAPC (45 nm)/mer-Ir(C\hat{ }C^{diMePh})₃ (5 nm) /UGH2: mer-Ir(C\hat{ }C^{diMePh})₃ (30 nm, 18%)/UGH2 (5 nm)/TmPyPB (30 nm)/Liq (1 nm)/Al (150 nm, cathode) was fabricated (see FIG. 12). In this use regard, was made of HAT-CN (hexaazatriphenylene-hexacarbonitrile) as a hole injection layer (HIL) material, TAPC (4,4′-cyclohexylidenebis[N,N-bis(4-methylphenyl)benzenamine]) as a hole transport layer (HTL) material, UGH2 (1,4-bis(triphenylsilyl)benzene) as a host, TmPyPB (1,3,5-tri(m-pyrid-3-yl-phenyl)benzene) as an electron transport layer (ETL) material, and Liq(8-quinolinolato lithium) as an electron injection layer (EIL) material.

### Comparative Example 1

A blue phosphorescent OLED was fabricated in the same manner as in Example 1, with the exception of using mer-Ir(C\hat{ }C^{H})₃ synthesized in Comparative Synthesis Example 3.

### Experimental Example 2

In Example 1 and Comparative Example 1, the singlet/triplet energy levels of each material used in the devices were measured, and the results are presented in FIG. 12.

As can be seen in FIG. 12, HAT-CN served to reduce the driving voltage of the device to the deep-lying LUMO level thereof and was used as a hole injection layer (HIL) to facilitate the injection of holes into the hole transport layer, TAPC. In the light-emitting layer, UGH2 with high triplet energy (T1=3.50 eV) was employed as the host material, ensuring efficient energy transfer from the host to the Ir dopant (for mer-Ir(C\hat{ }CH)3, T₁=3.22 eV; for mer-Ir(C\hat{ }C^{diMePh})₃, T₁=3.20 eV). Furthermore, each Ir dopant (mer-Ir(C\hat{ }C^{H})₃ or mer-Ir(C\hat{ }C^{diMePh})₃) layer and the UGH2 layer were respectively deposited on the front and back of the [UGH2: mer-Ir(C\hat{ }C^{H})₃] layer {or [UGH2: mer-Ir(C\hat{ }C^{diMePh})₃] layer}. This arrangement prevented exciton quenching at the TAPC (T₁=2.98 eV)/EML/TmPyPB (T₁=2.75 eV) interface and enabled effective carrier confinement in the NHC-Ir (III) complex-doped light-emitting layer. TmPyPB and Liq were employed as the electron transport layer (ETL) and the electron injection layer (EIL), respectively.

### Experimental Example 3

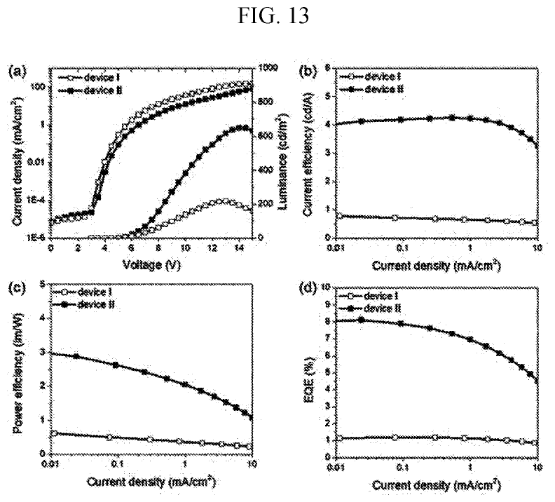

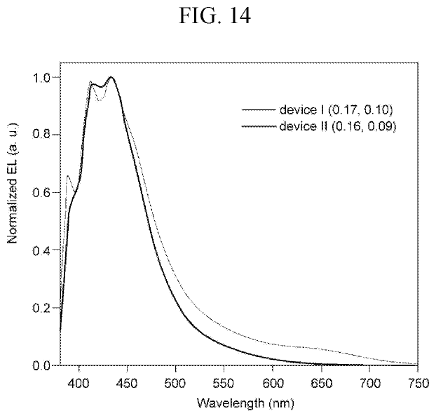

The OLEDs of Example 1 and Comparative Example 1 were measured for turn-on voltage, power efficiency (PE)—current density (J)—current efficiency (CE) properties, and external quantum efficiency (EQE), and the results are summarized in Table 6 and depicted in FIG. 13. Electroluminescence spectra of the OLEDs of Example 1 and Comparative Example 1 were measured and are depicted in FIG. 14.

TABLE 6

| | turn-on | CIE | max EQE | max CE | max PE |
|---|---|---|---|---|---|
| | voltage (V)^{b} | (x, y)^{c} | (%) | (Cd/A) | (lm/W) |
| Comparative | 4.7 | (0.17, | 1.2 | 1.0 | 0.6 |
| Example 1 | | 0.10) | | | |
| Example 1 | 4.2 | (0.16, | 8.1 | 4.3 | 2.9 |
| | | 0.09) | | | |

The devices of Example 1 and Comparative Example 1 exhibited similar turn-on voltage values (1 cd/m²), 4.7 V and 4.2 V, respectively (see Table 6).

As can be seen in FIG. 13, the device of Example 1 had an EQE of 8.1%, a PE of 2.9 lm/W, and a CE of 4.3 cd/A while the device of Comparative Example 1 had an EQE of 1.2%, a PE of 0.6 lm/W, and a CE of 1.0 cd/A. Thus, the device of Example 1, which included mer-Ir(C\hat{ }C^{diMePh})₃, demonstrated higher EQE, PE, and CE values than the device of Comparative Example 1, which contained mer-Ir(C\hat{ }C^{H})₃. The superior performance of Example 1 that included the diMePh-substituted mer-Ir(C\hat{ }C^{diMePh})₃ can be understood from the nearly doubled solid-state Φ_{PL} value (the solid-state Φ_{PL} value was 26.9% for (mer-Ir(C\hat{ }C^{H})₃ and 49.1% for mer-Ir(C\hat{ }C^{diMePh})₃). Considering that bulky substituents reduce intermolecular quenching processes (primarily triplet-triplet annihilation) to decrease the photoluminescence quantum yield in the emissive layer of a device, the molecular geometric structure of the Ir complex restricted by the diMePh substituent could enhance the device's performance. In fact, when comparing film Φ_{PL} based on the change in the Ir doping concentration (5-20 wt %) in the PMMA medium, an increase in the content of the Ir complex (either mer-Ir(C\hat{ }C^{H})₃ or mer-Ir(C\hat{ }C^{diMePh})₃) was found to lead to much more significantly decreasing the film Φ_{PL} of mer-Ir(C\hat{ }C^{H})₃ (from 26.9% in a 5 wt % film to 11.3% in a 20 wt % film) than that of mer-Ir(C\hat{ }C^{diMePh})₃ (from 49.1% in a 5 wt % film to 36.1% in a 20 wt % film). This clearly demonstrated that concentration quenching processes are more actively occurring in the mer-Ir(C\hat{ }C^{H})₃-doped PMMA film than in the mer-Ir(C\hat{ }C^{diMePh})₃ film, and also affirmed the positive role of the bulky aryl group in device performance.

As shown in FIG. 14, the electroluminescent (EL) spectra demonstrate structured emission features with peak emissions (λₘₐₓ) at 393 (sh), 414, and 433 nm for the device from Comparative Example 1 and at 393 (sh), 414, and 433 nm for the device from Example 1. These were similar to the steady-state PL (photoluminescence) spectra (see FIG. 3), indicating that the EL spectra originated from exciton formation of the NHC-Ir(III) complex in the light-emitting layer.

The devices from Comparative Example 1 and Example 1 displayed CIE chromaticity diagram (x, y) coordinates of (0.17, 0.10) and (0.16, 0.09) respectively, both representing deep blue coordinates. These results suggest that the deep blue emission efficiency of the Ir(C\hat{ }C)₃-type Ir(III) dopant material synthesized with a bulky xylene substituent can be improved for actual application in phosphorescent OLEDs.

### Example 2

mer-Ir(C\hat{ }C^{diMePh})₃ synthesized in Synthesis Example 2 and Ad-Cz synthesized in Synthesis Example 3 were used to fabricated blue phosphorescent OLEDs with the structure of ITO (150 nm, anode)/HAT-CN (10 nm)/TAPC (45 nm)/mer-Ir(C\hat{ }C^{diMePh})₃ (5 nm)/Ad-Cz: mer-Ir(C\hat{ }C^{diMePh})₃ (30 nm, 18%)/Ad-Cz (5 nm)/TmPyPB (30 nm)/Liq (1 nm)/Al (150 nm, cathode). In this regard, use was made of HAT-CN (hexaazatriphenylene-hexacarbonitrile) as a hole injection layer (HIL) material, TAPC (4,4′-cyclohexylidenebis[N,N-bis(4-methylphenyl)benzenamine]) as a hole transport layer (HTL) material, TmPyPB (1,3,5-tri(m-pyrid-3-yl-phenyl)benzene) as an electron transport layer (ETL) material, and Liq (8-quinolinolato lithium) as an electron injection layer (EIL) material.

### Comparative Example 2

A blue phosphorescent OLED was fabricated in the same manner as in Example 2, with the exception of using Cb-Cz (Exact Mass: 628.19, Molecular Weight: 628.72). The structure of Cb-Cz is as follows.

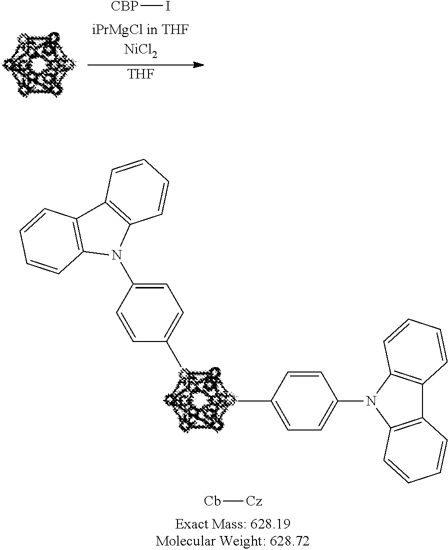

### Experimental Example 4

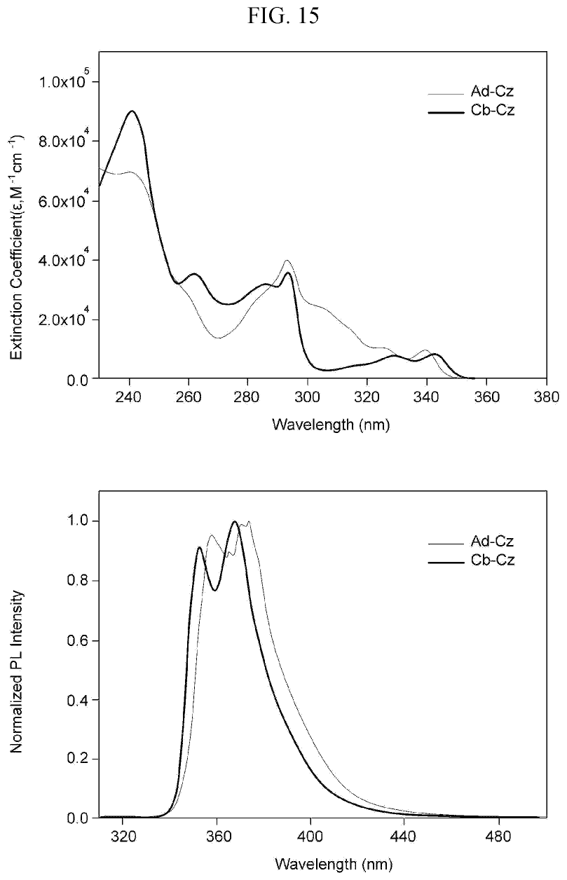

The host materials used in Example 2 and Comparative Example 2 (Ad-Cz and Cb-Cz) were analyzed for photophysical properties. Steady-state absorption and emission spectra of each material were measured in CH₂Cl₂ solution. The measurements are summarized in Table 7 and depicted in FIG. 15.

TABLE 7

| | Abs. λ | Em. λ | Stokes shift | T₁ | E_{HOMO}^{exp} | E_{LUMO}^{exp} |
|---|---|---|---|---|---|---|
| Compounds | [nm] | [nm] | [cm⁻¹] | (eV) | (eV) | (eV) |
| Ad-Cz | 293, 328, 342 | 357, 373 | 1229 | 3.05 | −5.63 | −1.97 |
| Cb-Cz | 293, 325, 338 | 352, 367 | 1177 | 3.05 | −5.78 | −2.13 |

### Experimental Example 5

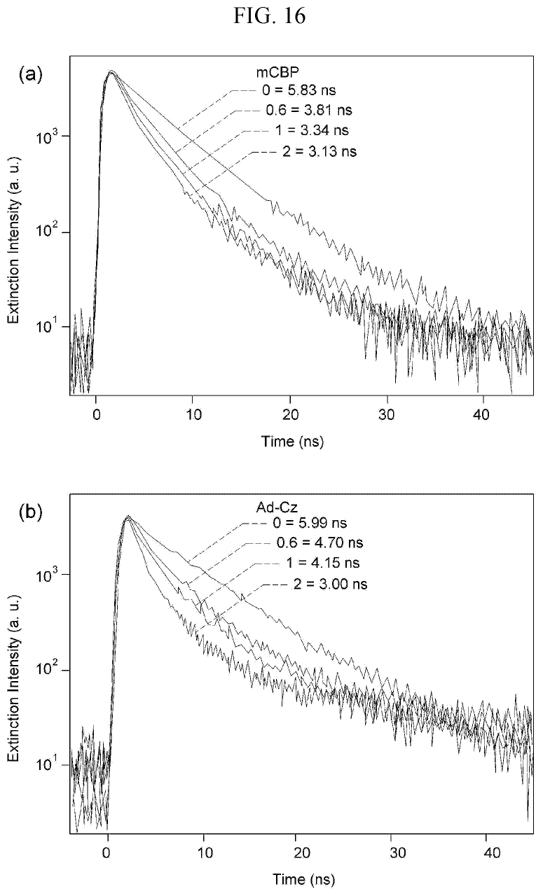

To confirm the energy transfer of compound Ad-Cz used as the host in the OLED of Example 2, Sample 1 organic EL was fabricated in the same manner as in Example 2, with the exception of using compound Ad-Cz as the host and FIrpic as the dopant, and was measured for luminance intensity. The results were presented in FIG. 16. For comparison, Control Sample 1 was prepared in the same manner as Example 2, with the exception of using mCBP as the host and FIrpic as the dopant.

1. An organic electroluminescence device, comprising: an anode; a cathode; and at least one organic layer disposed between the anode and the cathode,
wherein the at least one organic layer comprises a hole transport region, a light-emitting layer, and an electron transport region,
the light-emitting layer comprises an iridium complex represented by the following Chemical Formula 1 and a compound represented by the following Chemical Formula 2: 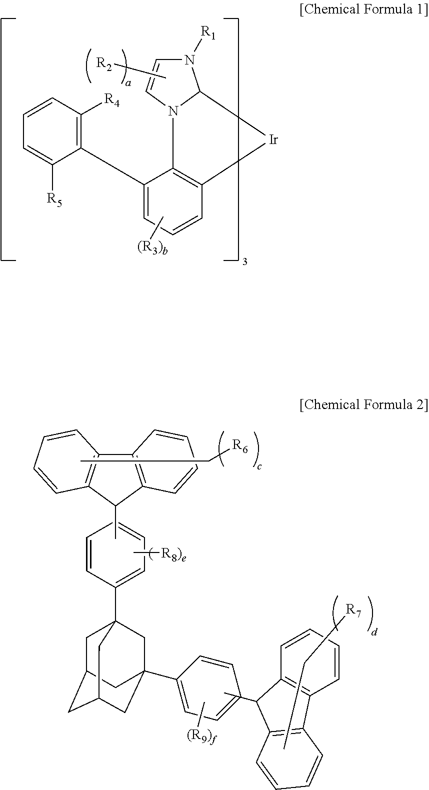
(wherein,
R₁ is an alkyl of C₁-C₂₀,
a is an integer of 0 to 2,
b is an integer of 0 to 3,
R₂ and R₃ are same or different and are each independently selected from the group consisting of a hydrogen atom, a deuterium atom, a halogen, a cyano, an alkyl of C₁-C₂₀, an alkenyl of C₂-C₄₀, an alkynyl of C₂-C₂₀, a cycloalkyl of C₃-C₂₀, a heterocycloalkyl of 3 to 20 nuclear atoms, an aryl of C₆-C₂₀, a heteroaryl of 5 to 20 nuclear atoms, an alkyloxy of C₁-C₂₀, and an aryloxy of C₆-C₂₀,
R₄ and R₅ are same or different and are each independently a hydrogen atom or an alkyl of C₁-C₂₀, with at least one thereof being an alkyl of C₁-C₂₀,
c and d are each an integer of 0 to 8,
e and f are each an integer of 0 to 4, and
R₆ to R₉ are same or different and are each independently selected from the group consisting of a hydrogen atom, a deuterium atom, a halogen, a cyano, an alkyl of C₁-C₂₀, an alkenyl of C₂-C₄₀, an alkynyl of C₂-C₂₀, a cycloalkyl of C₃-C₂₀, a heterocycloalkyl of 3 to 20 nuclear atoms, an aryl of C₆-C₂₀, a heteroaryl of 5 to 20 nuclear atoms, an alkyloxy of C₁-C₂₀, and an aryloxy of C₆-C₂₀).

2. The organic electroluminescence device of claim 1, wherein the iridium complex represented by Chemical Formula 1 and the host represented by Chemical Formula 2 are contained at a weight ratio of 1:99-30:70.

3. The organic electroluminescence device of claim 1, wherein iridium complex represented by Chemical Formula 1 is an iridium complex represented by the following Chemical Formula 1a: 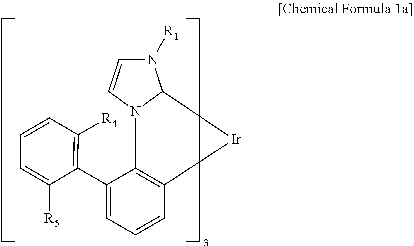
(wherein,
R₁, R₄ and R₅ are each defined as in claim 1).

4. The organic electroluminescence device of claim 1, wherein the 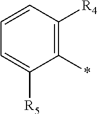
moiety iridium complex represented by Chemical Formula 1 is bonded to the benzene ring of the 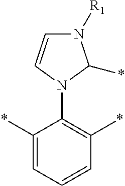
moiety at an angle of 0 to 90° with regard to the plane of the benzene ring.

5. The organic electroluminescence device of claim 4, wherein the 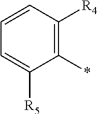
moiety is orthogonal to the plane of the 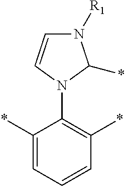
moiety and is bonded to the benzene ring.

6. The organic electroluminescence device of claim 1, wherein R₁, R₄, and R₅ are same or different and are each independently selected from the group consisting of methyl, ethyl, n-propyl, iso-propyl, n-butyl, iso-butyl or sec-butyl, and tert-butyl.

7. The organic electroluminescence device of claim 1, wherein the iridium complex represented by Chemical Formula 1 is an iridium complex represented by the following Chemical Formula 1b or 1c: 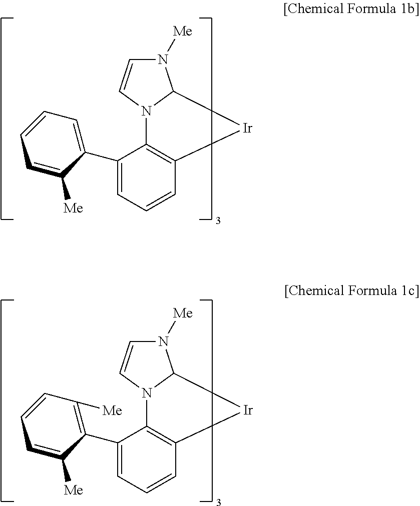
(wherein Me is methyl)

8. The organic electroluminescence device of claim 1, wherein the compound represented by Chemical Formula 2 is a compound represented by the following Chemical Formula 2a: 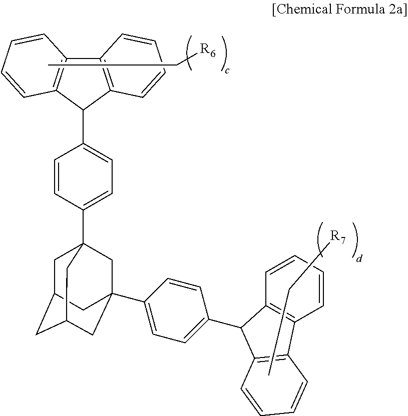
(wherein c, d, R., and R are each defined as in claim 1).

9. The organic electroluminescence device of any one of claims 1 to 8, wherein the device produces blue light emission with CIE coordinates where the x-value is 0.15-0.25 and the y-value is 0.08-0.20.
